(19) United States
(12) Patent Application Publication
(10) Pub. No.: US 2016/0072091 A1
(43) Pub. Date: Mar. 10, 2016

(54) ORGANIC ELECTROLUMINESCENT DEVICE

(71) Applicant: SAMSUNG DISPLAY CO., LTD., Yongin-City (KR)

(72) Inventors: Ichiro IMADA, Yokohama (JP); Naoya SAKAMOTO, Yokohama (JP)

(21) Appl. No.: 14/798,786

(22) Filed: Jul. 14, 2015

(30) Foreign Application Priority Data
Sep. 9, 2014 (JP) 2014-183124
Sep. 9, 2014 (JP) 2014-183127

(51) Int. Cl. H01L 51/50; H01L 51/00

(52) U.S. Cl. CPC H01L 51/5064; H01L 51/0059; H01L 51/006; H01L 51/0061; H01L 51/0072; H01L 51/0074; H01L 51/0073; H01L 51/0058; H01L 51/5206

(57) ABSTRACT

An organic electroluminescent device includes an anode, an emission layer, an anode-side hole transport layer on the anode and the emission layer, the anode-side hole transport layer including an anode-side hole transport material and the anode-side hole transport layer being doped with an electron accepting material, an intermediate hole transport material layer between the anode-side hole transport layer and the emission layer, the intermediate hole transport layer including an intermediate hole transport material, and an emission layer-side hole transport material between the intermediate hole transport material layer and the emission layer and adjacent to the emission layer, the emission layer-side hole transport material layer including an emission layer-side hole transport material represented by the following General Formula (1):

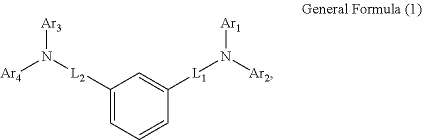

where Ar₁, Ar₂, Ar₃, Ar₄, L₁, and L₂ are as defined in the specification.

### CROSS-REFERENCE TO RELATED APPLICATIONS

Japanese Patent Application Nos. 2014-183124, filed on Sep. 9, 2014, and 2014-183127, filed on Sep. 9, 2014, in the Japanese Patent Office, and entitled: “Organic Electroluminescent Device,” is incorporated by reference herein in its entirety.

### BACKGROUND

1. Field

Embodiments relate to an organic electroluminescent device.

2. Description of the Related Art

Development of an organic electroluminescence display is being conducted. In addition, the development of a self-luminescent organic electroluminescent device used in the organic electroluminescence display is also being actively conducted.

A organic electroluminescent device may have a stacked structure obtained by stacking, e.g. an anode, a hole transport layer, an emission layer, an electron transport layer and a cathode one by one.

In such an organic electroluminescent device, holes and electrons injected from the anode and the cathode recombine in the emission layer and produce excitons. In addition, the produced excitons transit to a ground state while emitting light.

### SUMMARY

Embodiments are directed to an organic electroluminescent device including an anode, an emission layer, an anode-side hole transport layer on the anode and the emission layer, the anode-side hole transport layer including an anode-side hole transport material and the anode-side hole transport layer being doped with an electron accepting material, an intermediate hole transport material layer between the anode-side hole transport layer and the emission layer, the intermediate hole transport layer including an intermediate hole transport material, and an emission layer-side hole transport material between the intermediate hole transport material layer and the emission layer and adjacent to the emission layer, the emission layer-side hole transport material layer including an emission layer-side hole transport material represented by the following General Formula (1):

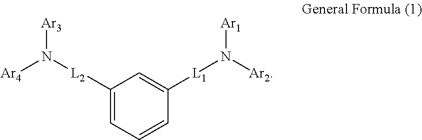

In the above General Formula (1), Ar₁, Ar₂, Ar₃, and Ar₃ are each independently a substituted or unsubstituted aryl group having 6 to 50 ring carbon atoms or a substituted or unsubstituted heteroaryl group having 5 to 50 ring carbon atoms, and L₁ and L₂ are each independently a direct linkage, a substituted or unsubstituted arylene group having 6 to 18 ring carbon atoms, or a substituted or unsubstituted heteroarylene group having 5 to 15 ring carbon atoms.

The intermediate hole transport material may be a compound represented by the following General Formula (2):

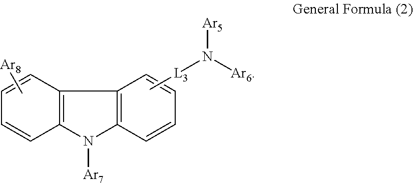

In the above General Formula (2), Ar₅, Ar₆, and Ar₇ are each independently a substituted or unsubstituted aryl group having 6 to 50 ring carbon atoms or a substituted or unsubstituted heteroaryl group having 5 to 50 ring carbon atoms, Ar₈ is a substituted or unsubstituted aryl group having 6 to 50 ring carbon atoms, a substituted or unsubstituted heteroaryl group having 5 to 50 ring carbon atoms, or a substituted or unsubstituted alkyl group having 1 to 50 carbon atoms, and L₃ is a direct linkage, a substituted or unsubstituted arylene group having 6 to 50 ring carbon atoms, or a substituted or unsubstituted heteroarylene group having 5 to 50 ring carbon atoms.

The electron accepting material may have a lowest unoccupied molecular orbital (LUMO) level of from about −9.0 eV to about −4.0 eV.

The anode-side hole transport layer may be adjacent to the anode.

The anode-side hole transport material of the anode-side hole transport layer may be a compound represented by the following General Formula (2):

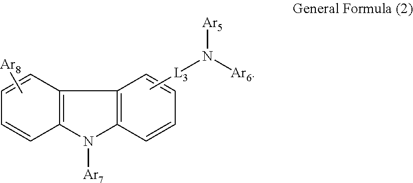

In the above General Formula (2), Ar₅, Ar₆, and Ar₇ are each independently a substituted or unsubstituted aryl group having 6 to 50 ring carbon atoms or a substituted or unsubstituted heteroaryl group having 5 to 50 ring carbon atoms, Ar₈ is a substituted or unsubstituted aryl group having 6 to 50 ring carbon atoms, a substituted or unsubstituted heteroaryl group having 5 to 50 ring carbon atoms, or a substituted or unsubstituted alkyl group having 1 to 50 carbon atoms, and L₃ is a direct linkage, a substituted or unsubstituted arylene group having 6 to 50 ring carbon atoms, or a substituted or unsubstituted heteroarylene group having 5 to 50 ring carbon atoms.

The emission layer may include an emission material that emits light via a singlet excited state.

The emission layer may include a compound represented by the following General Formula (3):

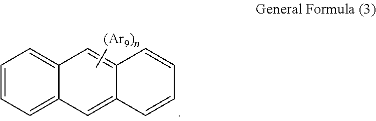

In the above General Formula (3), each Ar₉ is independently a hydrogen atom, a deuterium atom, a substituted or unsubstituted alkyl group having 1 to 50 carbon atoms, a substituted or unsubstituted cycloalkyl group having 3 to 50 ring carbon atoms, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 ring carbon atoms, a substituted or unsubstituted arylthio group having 6 to 50 ring carbon atoms, a substituted or unsubstituted alkoxycarbonyl group having 2 to 50 carbon atoms, a substituted or unsubstituted aryl group having 6 to 50 ring carbon atoms, a substituted or unsubstituted heteroaryl group having 5 to 50 ring carbon atoms, a substituted or unsubstituted silyl group, a carboxyl group, a halogen atom, a cyano group, a nitro group or a hydroxyl group, and n is an integer from 1 to 10.

Embodiments are also directed to an organic electroluminescent device including an anode an emission layer an anode-side hole transport layer between the anode and the emission layer, the anode-side hole transport layer including an electron accepting material an intermediate hole transport material layer provided between the anode-side hole transport layer and the emission layer, the intermediate hole transport material layer including an intermediate hole transport material, and an emission layer-side hole transport material layer between the intermediate hole transport material layer and the emission layer and adjacent to the emission layer, the emission layer-side hole transport material layer including an emission layer-side hole transport material represented by the following General Formula (1):

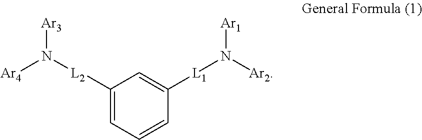

In the above General Formula (1), Ar₁, Ar₂, Ar₃, and Ar₄ are each independently a substituted or unsubstituted aryl group having 6 to 50 ring carbon atoms or a substituted or unsubstituted heteroaryl group having 5 to 50 ring carbon atoms, and L₁ and L₂ are each independently a direct linkage, a substituted or unsubstituted arylene group having 6 to 18 ring carbon atoms, or a substituted or unsubstituted heteroarylene group having 5 to 15 ring carbon atoms.

The intermediate hole transport material may be a compound represented by the following General Formula (2):

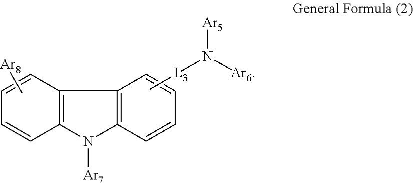

In the above General Formula (2), Ar₅, Ar₆, and Ar₇ are each independently a substituted or unsubstituted aryl group having 6 to 50 ring carbon atoms or a substituted or unsubstituted heteroaryl group having 5 to 50 ring carbon atoms, Ar₈ is a substituted or unsubstituted aryl group having 6 to 50 ring carbon atoms, a substituted or unsubstituted heteroaryl group having 5 to 50 ring carbon atoms, or a substituted or unsubstituted alkyl group having 1 to 50 carbon atoms, and L₃ is a direct linkage, a substituted or unsubstituted arylene group having 6 to 50 ring carbon atoms, or a substituted or unsubstituted heteroarylene group having 5 to 50 ring carbon atoms.

The electron accepting material may have a lowest unoccupied molecular orbital (LUMO) level of from about −9.0 eV to about −4.0 eV.

The anode-side hole transport layer may be adjacent to the anode.

The emission layer may include an emission material emitting light via a singlet excited state.

The emission layer may include a compound represented by the following General Formula (3):

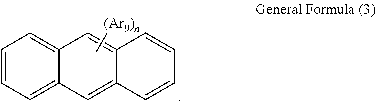

In the above General Formula (3), each Ar₉ is independently a hydrogen atom, a deuterium atom, a substituted or unsubstituted alkyl group having 1 to 50 carbon atoms, a substituted or unsubstituted cycloalkyl group having 3 to 50 ring carbon atoms, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 ring carbon atoms, a substituted or unsubstituted arylthio group having 6 to 50 ring carbon atoms, a substituted or unsubstituted alkoxycarbonyl group having 2 to 50 carbon atoms, a substituted or unsubstituted aryl group having 6 to 50 ring carbon atoms, a substituted or unsubstituted heteroaryl group having 5 to 50 ring carbon atoms, a substituted or unsubstituted silyl group, a carboxyl group, a halogen atom, a cyano group, a nitro group, or a hydroxyl group, and n is an integer from 1 to 10.

### BRIEF DESCRIPTION OF THE DRAWING

Features will become apparent to those of skill in the art by describing in detail exemplary embodiments with reference to the attached drawing in which:

FIG. 1 illustrates a schematic diagram for explaining the configuration of an organic electroluminescent device according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “between” two layers, it can be the only layer between the two layers, or one or more intervening layers may also be present. Like reference numerals refer to like elements throughout.

### 1-1. Configuration of Organic Electroluminescent Device Including Anode-Side Hole Transport Material and an Anode-Side Hole Transport Layer Doped with an Electron Accepting Material

### 1-1-1. Whole Configuration

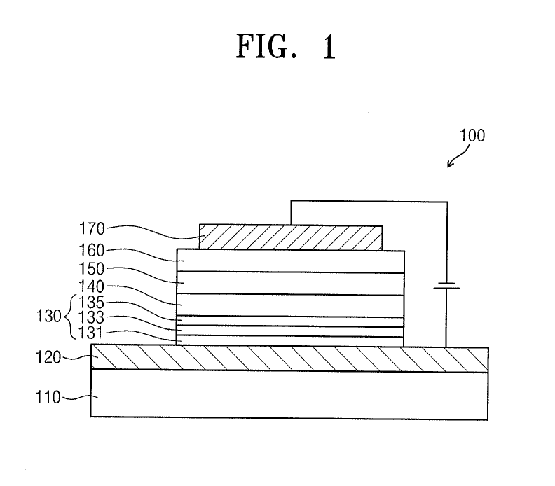

First, on the basis of FIG. 1, the whole configuration of an organic electroluminescent device 100 according to an embodiment will be described.

As shown in FIG. 1, an organic electroluminescent device 100 according to an example embodiment may include a substrate 110, a first electrode 120 disposed on the substrate 110, a hole transport layer 130 disposed on the first electrode 120, an emission layer 140 disposed on the hole transport layer 130, an electron transport layer 150 disposed on the emission layer 140, an electron injection layer 160 disposed on the electron transport layer 150 and a second electrode 170 disposed on the electron injection layer 160. Here, the hole transport layer 130 may be formed to have a multi-layer structure composed of a plurality of layers 131, 133 and 135.

### 1-1-2. Configuration of Substrate

The substrate 110 may be a substrate suitable for a general organic electroluminescent device. For example, the substrate 110 may be a glass substrate, a semiconductor substrate or a transparent plastic substrate.

### 1-1-3. Configuration of First Electrode

The first electrode 120 may be, e.g. an anode, and may be formed on the substrate 110 using an evaporation method, a sputtering method, etc. The first electrode 120 may be formed as a transmission type electrode using a metal, an alloy, a conductive compound, etc. having large work function. The first electrode 120 may be formed using, e.g. indium tin oxide (ITO), indium zinc oxide (IZO), tin oxide (SnO₂), zinc oxide (ZnO), etc. having good transparency and conductivity. In some implementations, the first electrode 120 may be formed as a reflection type electrode using magnesium (Mg), aluminum (Al), etc.

### 1-1-4. Configuration of Hole Transport Layer

The hole transport layer 130 may include a hole transport material and have hole transporting function. The hole transport layer 130 may be formed, for example, on the first electrode 120 to a layer thickness (total layer thickness of a stacked structure) of about 10 nm to about 150 nm.

The hole transport layer 130 of the organic electroluminescent device 100 according to an embodiment may be formed as a multi-layer by stacking from the first electrode 120, an anode-side hole transport layer 131, an intermediate hole transport material layer 133 and an emission layer-side hole transport layer 135 one by one.

(1-1-4-1. Configuration of Anode-Side Hole Transport Layer)

The anode-side hole transport layer 131 may be a layer including an anode-side hole transport material. The anode-side hole transport layer 131 may be doped with an electron accepting material. For example, the anode-side hole transport layer 131 may be formed on the first electrode 120.

The anode-side hole transport layer 131 may be doped with the electron accepting material. The anode-side hole transport layer 131 may improve hole injection property from the first electrode 120. The anode-side hole transport layer 131 may be provided near the first electrode 120, or, for example, adjacent to the first electrode 120.

The anode-side hole transport material included in the anode-side hole transport layer 131 may be a suitable hole transport material. Examples of the anode-side hole transport material included in the anode-side hole transport layer 131 may include 1,1-bis[(di-4-tolylamino)phenyl]cyclohexane (TAPC), a carbazole derivative such as N-phenyl carbazole, polyvinyl carbazole, etc., N,N′-bis(3-methylphenyl)-N,N′-diphenyl-[1,1-biphenyl]-4,4′-diamine (TPD), 4,4′,4″-tris(N-carbazolyl)triphenylamine (TCTA), N,N″-di(1-naphthyl)-N,N′-diphenylbenzidine (NPB), etc.

The electron accepting material included in the anode-side hole transport layer 131 may be a suitable electron accepting material. The electron accepting material included in the anode-side hole transport layer 131 may have a LUMO level from about −9.0 eV to about −4.0 eV, or, for example, may have the LUMO level from about −6.0 eV to about −4.0 eV.

Here, examples of the electron accepting material having the LUMO level from about −9.0 eV to about −4.0 eV may include the compounds represented by the following Formulae 4-1 to 4-14.

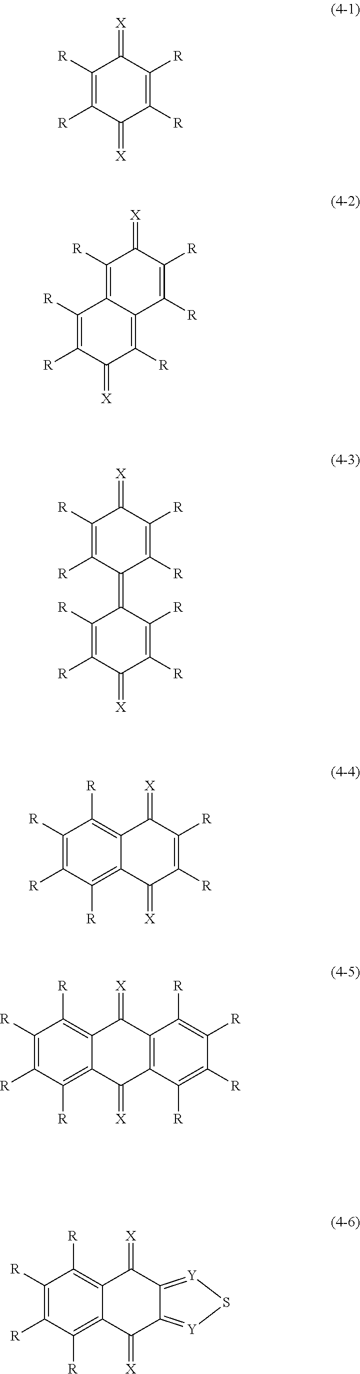

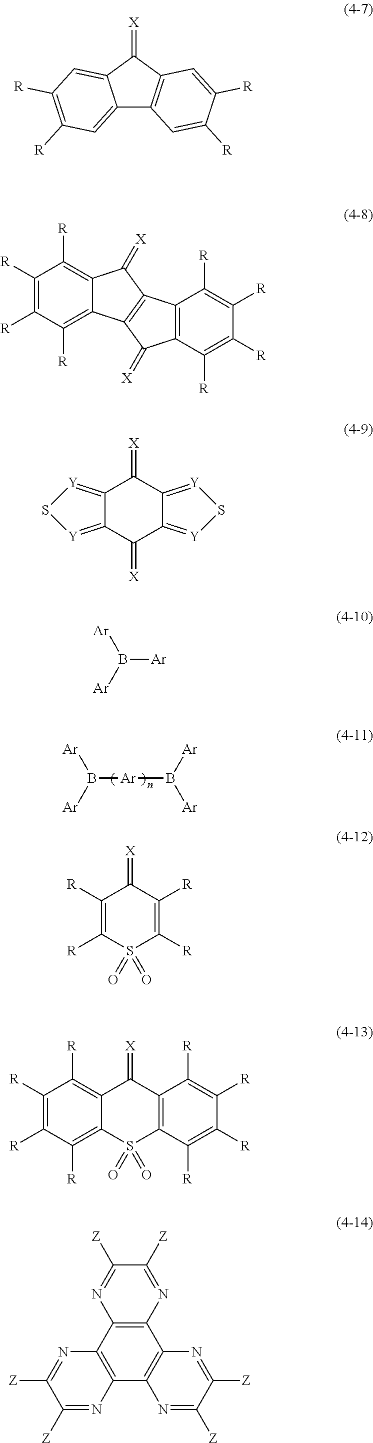

In the above Formulae 4-1 to 4-14, R is a hydrogen atom, a deuterium atom, a halogen atom, a fluoroalkyl group having 1 to 50 carbon atoms, a cyano group, an alkoxy group having 1 to 50 carbon atoms, an alkyl group having 1 to 50 carbon atoms, an aryl group having 6 to 50 carbon atoms or a heteroaryl group having 5 to 50 ring carbon atoms. Ar is an aryl group having an electron withdrawing substituent or an unsubstituted aryl group having 6 to 50 ring carbon atoms or a substituted or unsubstituted heteroaryl group having 5 to 50 ring carbon atoms. Y is a methine group (—CH═) or a nitrogen atom (—N═). Z is a pseudohalogen atom or a sulfur (S) atom, n is an integer of 10 and less, and X is one of the substituents represented by the following formulae X1 to X7.

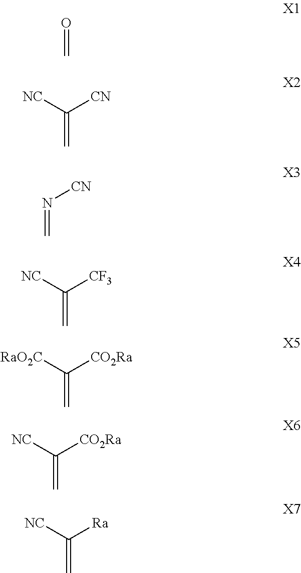

In the above Formulae X1 to X7, Ra is a hydrogen atom, a deuterium atom, a halogen atom, a fluoroalkyl group having 1 to 50 carbon atoms, a cyano group, an alkoxy group having 1 to 50 carbon atoms, an alkyl group having 1 to 50 carbon atoms, a substituted or unsubstituted aryl group having 6 to 50 ring carbon atoms or a substituted or unsubstituted heteroaryl group having 5 to 50 ring carbon atoms.

Examples of the substituted or unsubstituted aryl group having 6 to 50 ring carbon atoms represented by R, Ar and Ra may include a phenyl group, a 1-naphthyl group, a 2-naphthyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group, a 1-naphthacenyl group, a 2-naphthacenyl group, a 9-naphthacenyl group, a 1-pyrenyl group, a 2-pyrenyl group, a 4-pyrenyl group, a 2-biphenylyl group, a 3-biphenylyl group, a 4-biphenylyl group, a p-terphenyl-4-yl group, a p-terphenyl-3-yl group, a p-terphenyl-2-yl group, a m-terphenyl-4-yl group, a m-terphenyl-3-yl group, a m-terphenyl-2-yl group, an o-tolyl group, a m-tolyl group, a p-tolyl group, a p-t-butylphenyl group, a p-(2-phenylpropyl)phenyl group, a 3-methyl-2-naphthyl group, a 4-methyl-1-naphthyl group, a 4-methyl-1-anthryl group, a 4′-methylbiphenylyl group, a 4″-t-butyl-p-terphenyl-4-yl group, a fluoranthenyl group, a fluorenyl group, etc.

Examples of the substituted or unsubstituted heteroaryl group having 5 to 50 ring carbon atoms represented by R, Ar and Ra may include a 1-pyrrolyl group, a 2-pyrrolyl group, a 3-pyrrolyl group, a pyridinyl group, a 2-pyridinyl group, a 3-pyridinyl group, a 4-pyridinyl group, a 1-indolyl group, a 2-indolyl group, a 3-indolyl group, a 4-indolyl group, a 5-indolyl group, a 6-indolyl group, a 7-indolyl group, a 1-isoindolyl group, a 2-isoindolyl group, a 3-isoindolyl group, a 4-isoindolyl group, a 5-isoindolyl group, a 6-isoindolyl group, a 7-isoindolyl group, a 2-furyl group, a 3-furyl group, a 2-benzofuranyl group, a 3-benzofuranyl group, a 4-benzofuranyl group, a 5-benzofuranyl group, a 6-benzofuranyl group, a 7-benzofuranyl group, a 1-isobenzofuranyl group, a 3-isobenzofuranyl group, a 4-isobenzofuranyl group, a 5-isobenzofuranyl group, a 6-isobenzofuranyl group, a 7-isobenzofuranyl group, a quinolyl group, a 3-quinolyl group, a 4-quinolyl group, a 5-quinolyl group, a 6-quinolyl group, a 7-quinolyl group, a 8-quinolyl group, a 1-isoquinolyl group, a 3-isoquinolyl group, a 4-isoquinolyl group, a 5-isoquinolyl group, a 6-isoquinolyl group, a 7-isoquinolyl group, a 8-isoquinolyl group, a 2-quinoxalinyl group, a 5-quinoxalinyl group, a 6-quinoxalinyl group, a 1-carbazolyl group, a 2-carbazolyl group, a 3-carbazolyl group, a 4-carbazolyl group, a 9-carbazolyl group, a 1-phenanthridinyl group, a 2-phenanthridinyl group, a 3-phenanthridinyl group, a 4-phenanthridinyl group, a 6-phenanthridinyl group, a 7-phenanthridinyl group, a 8-phenanthridinyl group, a 9-phenanthridinyl group, a 10-phenanthridinyl group, a 1-acridinyl group, a 2-acridinyl group, a 3-acridinyl group, a 4-acridinyl group, a 9-acridinyl group, a 1,7-phenanthroline-2-yl group, a 1,7-phenanthroline-3-yl group, a 1,7-phenanthroline-4-yl group, a 1,7-phenanthroline-5-yl group, a 1,7-phenanthroline-6-yl group, a 1,7-phenanthroline-8-yl group, a 1,7-phenanthroline-9-yl group, a 1,7-phenanthroline-10-yl group, a 1,8-phenanthroline-2-yl group, a 1,8-phenanthroline-3-yl group, a 1,8-phenanthroline-4-yl group, a 1,8-phenanthroline-5-yl group, a 1,8-phenanthroline-6-yl group, a 1,8-phenanthroline-7-yl group, a 1,8-phenanthroline-9-yl group, a 1,8-phenanthroline-10-yl group, a 1,9-phenanthroline-2-yl group, a 1,9-phenanthroline-3-yl group, a 1,9-phenanthroline-4-yl group, a 1,9-phenanthroline-5-yl group, a 1,9-phenanthroline-6-yl group, a 1,9-phenanthroline-7-yl group, a 1,9-phenanthroline-8-yl group, a 1,9-phenanthroline-10-yl group, a 1,10-phenanthroline-2-yl group, a 1,10-phenanthroline-3-yl group, a 1,10-phenanthroline-4-yl group, a 1,10-phenanthroline-5-yl group, a 2,9-phenanthroline-1-yl group, a 2,9-phenanthroline-3-yl group, a 2,9-phenanthroline-4-yl group, a 2,9-phenanthroline-5-yl group, a 2,9-phenanthroline-6-yl group, a 2,9-phenanthroline-7-yl group, a 2,9-phenanthroline-8-yl group, a 2,9-phenanthroline-10-yl group, a 2,8-phenanthroline-1-yl group, a 2,8-phenanthroline-3-yl group, a 2,8-phenanthroline-4-yl group, a 2,8-phenanthroline-5-yl group, a 2,8-phenanthroline-6-yl group, a 2,8-phenanthroline-7-yl group, a 2,8-phenanthroline-9-yl group, a 2,8-phenanthroline-10-yl group, a 2,7-phenanthroline-1-yl group, a 2,7-phenanthroline-3-yl group, a 2,7-phenanthroline-4-yl group, a 2,7-phenanthroline-5-yl group, a 2,7-phenanthroline-6-yl group, a 2,7-phenanthroline-8-yl group, a 2,7-phenanthroline-9-yl group, a 2,7-phenanthroline-10-yl group, a 1-phenazinyl group, a 2-phenazinyl group, a 1-phenothiazinyl group, a 2-phenothiazinyl group, a 3-phenothiazinyl group, a 4-phenothiazinyl group, a 10-phenothiazinyl group, a 1-fenoxaziny group, a 2-fenoxazinyl group, a 3-fenoxazinyl group, a 4-fenoxazinyl group, a 10-fenoxazinyl group, a 2-oxazolyl group, a 4-oxazolyl group, a 5-oxazolyl group, a 2-oxadiazolyl group, a 5-oxadiazolyl group, a 3-furazanyl group, a 2-thienyl group, a 3-thienyl group, a 2-methylpyrrole-1-yl group, a 2-methylpyrrole-3-yl group, a 2-methylpyrrole-4-yl group, a 2-methylpyrrole-5-yl group, a 3-methylpyrrole-1-yl group, a 3-methylpyrrole-2-yl group, a 3-methylpyrrole-4-yl group, a 3-methylpyrrole-5-yl group, a 2-t-butylpyrrole-4-yl group, a 3-(2-phenylpropyl)pyrrole-1-yl group, a 2-methyl-1-indolyl group, a 4-methyl-1-indolyl group, a 2-methyl-3-indolyl group, a 4-methyl-3-indolyl group, a 2-t-butyl-1-indolyl group, a 4-t-butyl-1-indolyl group, a 2-t-butyl-3-indolyl group, a 4-t-butyl-3-indolyl group, etc.

Examples of the fluoroalkyl group in the substituted or unsubstituted fluoroalkyl group having 1 to 50 carbon atoms represented by R and Ra may include a perfluoroalkyl group such as a trifluoromethyl group, a pentafluoroethyl group, a heptafluoropropyl group and a heptadecafluorooctane group, a monofluoromethyl group, a difluoromethyl group, a trifluoroethyl group, a tetrafluoropropyl group, an octafluoropentyl group, etc.

Examples of the substituted or unsubstituted alkyl group having 1 to 50 carbon atoms represented by R and Ra may include a methyl group, an ethyl group, a propyl group, an isopropyl group, a n-butyl group, a s-butyl group, an isobutyl group, a t-butyl group, a n-pentyl group, a n-hexyl group, a n-heptyl group, a n-octyl group, a hydroxymethyl group, a 1-hydroxyethyl group, a 2-hydroxyethyl group, a 2-hydroxyisobutyl group, a 1,2-dihydroxyethyl group, a 1,3-dihydroxyisopropyl group, a 2,3-dihydroxy-t-butyl group, a 1,2,3-trihydroxypropyl group, a chloromethyl group, a 1-chloroethyl group, a 2-chloroethyl group, a 2-chloroisobutyl group, a 1,2-dichloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 2-nitroisobutyl group, a 1,2-dinitroethyl group, a 1,3-dinitroisopropyl group, a 2,3-dinitro-t-butyl group, a 1,2,3-trinitropropyl group, a cyclopropyl group, a cyclobutyl group, a cyclopentyl group, a cyclohexyl group, a 4-methylcyclohexyl group, a 1-adamantyl group, a 2-adamantyl group, a 1-norbornyl group, a 2-norbornyl group, etc.

The substituted or unsubstituted alkoxy group having 1 to 50 carbon atoms represented by R and Ra may be a group represented by —OY. Examples of Y may include a methyl group, an ethyl group, a propyl group, an isopropyl group, a n-butyl group, a s-butyl group, an isobutyl group, a t-butyl group, a n-pentyl group, a n-hexyl group, a n-heptyl group, a n-octyl group, a hydroxymethyl group, a 1-hydroxyethyl group, a 2-hydroxyethyl group, a 2-hydroxyisobutyl group, a 1,2-dihydroxyethyl group, a 1,3-dihydroxyisopropyl group, a 2,3-dihydroxy-t-butyl group, a 1,2,3-trihydroxypropyl group, a chloromethyl group, a 1-chloroethyl group, a 2-chloroethyl group, a 1,2-chloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 2-nitroisobutyl group, a 1,2-dinitroethyl group, a 1,3-dinitroisopropyl group, a 2,3-dinitro-t-butyl group, a 1,2,3-trinitropropyl group, etc.

Examples of the halogen atom represented by R and Ra may include fluorine (F), chlorine (Cl), bromine (Br), iodine (I), etc.

Examples of compounds of the electron accepting material may include the following Compounds 4-15 and 4-16. For example, the LUMO level of Compound 4-15 may be about −4.40 eV, and the LUMO level of Compound 4-16 may be about −5.20 eV.

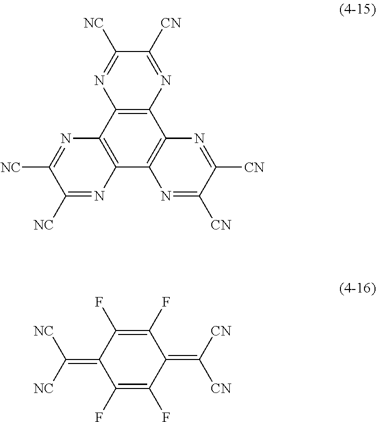 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F]

The doping of the electron accepting material may be an suitable amount for doping the anode-side hole transport layer 131. For example, the doping amount of the electron accepting material may be from about 0.1 wt % to about 50 wt % on the basis of the total amount of the anode-side hole transport material included in the anode-side hole transport layer 131. For example, the doping amount may be from about 0.5 wt % to about 5 wt %.

(1-1-4-2. Configuration of Intermediate Hole Transport Material Layer)

The intermediate hole transport material layer 133 may include an intermediate hole transport material. The intermediate hole transport material layer 133 may be formed on, for example, the anode-side hole transport layer 131.

The intermediate hole transport material included in the intermediate hole transport material layer 133 may be a suitable hole transport material. The intermediate hole transport material may include the above-mentioned hole transport materials as the anode-side hole transport materials.

In some implementations, the intermediate hole transport material may be a compound represented by the following General Formula (2).

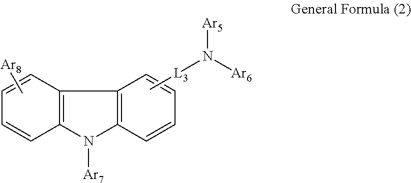

In the above General Formula (2), Ar₅, Ar₆, and Ar₇ are each independently a substituted or unsubstituted aryl group having 6 to 50 ring carbon atoms or a substituted or unsubstituted heteroaryl group having 5 to 50 ring carbon atoms, Ar₈ is a substituted or unsubstituted aryl group having 6 to 50 ring carbon atoms, a substituted or unsubstituted heteroaryl group having 5 to 50 ring carbon atoms or a substituted or unsubstituted alkyl group having 1 to 50 carbon atoms, L₃ is a direct linkage, a substituted or unsubstituted arylene group having 6 to 50 ring carbon atoms or a substituted or unsubstituted heteroarylene group having 5 to 50 ring carbon atoms.

Examples of Ar₅, Ar₆, and Ar₇ may include a phenyl group, a biphenyl group, a terphenyl group, a naphthyl group, an anthryl group, a phenanthryl group, a fluorenyl group, an indenyl group, a pyrenyl group, an acetonaphthenyl group, a fluoranthenyl group, a triphenylenyl group, a pyridyl group, a furanyl group, a pyranyl group, a thienyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a pyrazolyl group, a dibenzofuranyl group, a dibenzothienyl group, etc. For example, Ar₅, Ar₆, and Ar₇ may be the phenyl group, the biphenyl group, the terphenyl group, the fluorenyl group, the carbazolyl group, the dibenzofuranyl group, etc.

Examples of Ar₈ may include a phenyl group, a biphenyl group, a terphenyl group, a naphthyl group, an anthryl group, a phenanthryl group, a fluorenyl group, an indenyl group, a pyrenyl group, an acetonaphthenyl group, a fluoranthenyl group, a triphenylenyl group, a pyridyl group, a furanyl group, a pyranyl group, a thienyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a benzoimidazolyl group, a pyrazolyl group, a dibenzofuranyl group, a dibenzothienyl group, a methyl group, an ethyl group, a propyl group, an isopropyl group, a n-butyl group, etc. For example, Ar₈ may be the phenyl group, the biphenyl group, the terphenyl group, the fluorenyl group, the carbazolyl group, the dibenzofuranyl group, etc.

Examples of L₃ may include a phenylene group, a biphenylene group, a terphenylene group, a naphthalene group, an anthrylene group, a phenanthrylene group, a fluorenylene group, an indenylene group, a pyrenylene group, an acetonaphthenylene group, a fluoranthenylene group, a triphenylenylene group, a pyridylene group, a furanylene group, a pyranylene group, a thienylene group, a quinolylene group, an isoquinolylene group, a benzofuranylene group, a benzothienylene group, an indolylene group, a carbazolylene group, a benzoxazolylene group, a benzothiazolylene group, a kinokisariren group, a benzoimidazolylene group, a pyrazolylene group, a dibenzofuranylene group, a dibenzothienylene group, etc. For example, L₃ may be a direct linkage, the phenylene group, the biphenylene group, the terphenylene group, the fluorenylene group, the carbazolylene group or the dibenzofuranylene group.

Examples of the compound represented by General Formula (2) may include the following Compounds 2-1 to 2-16.

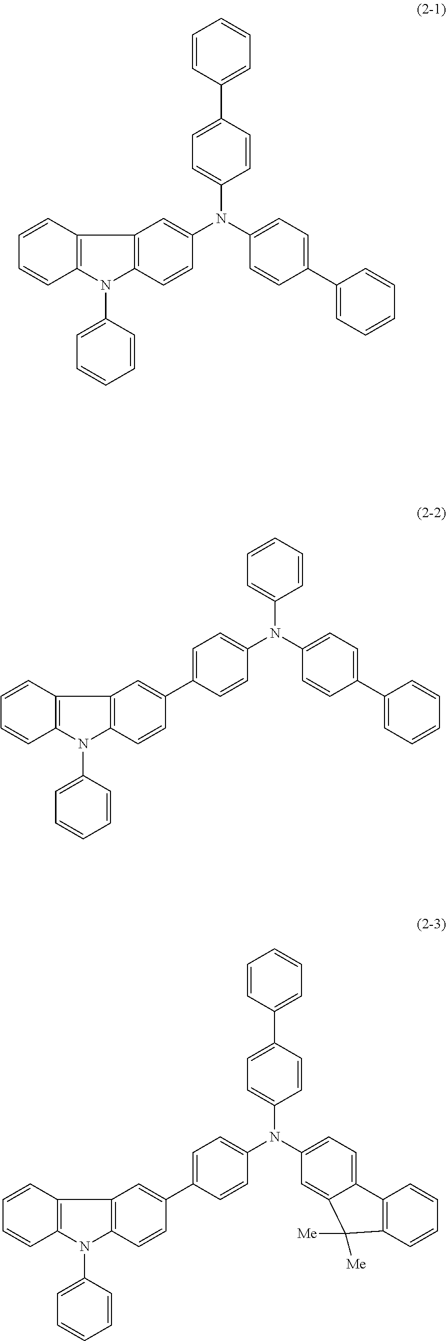

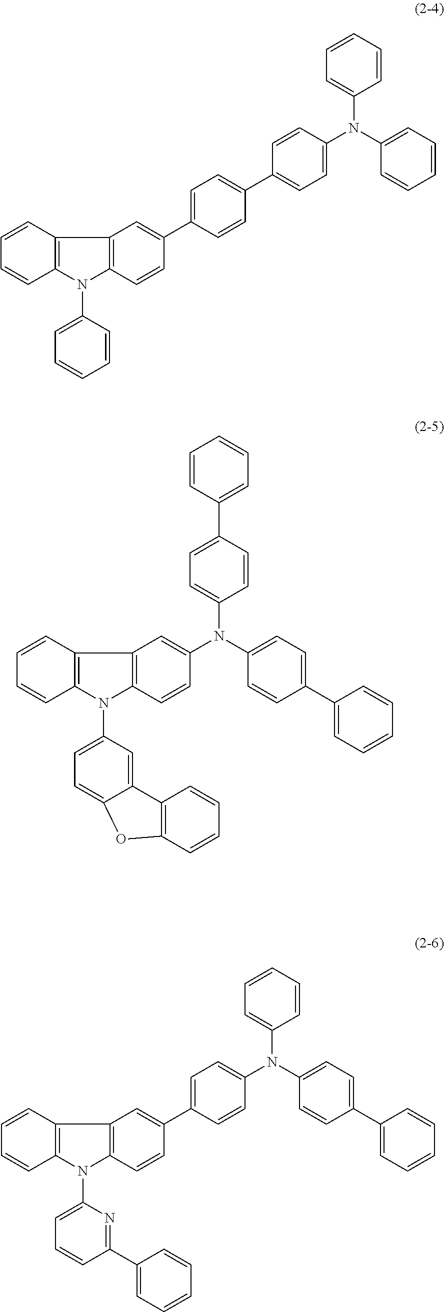

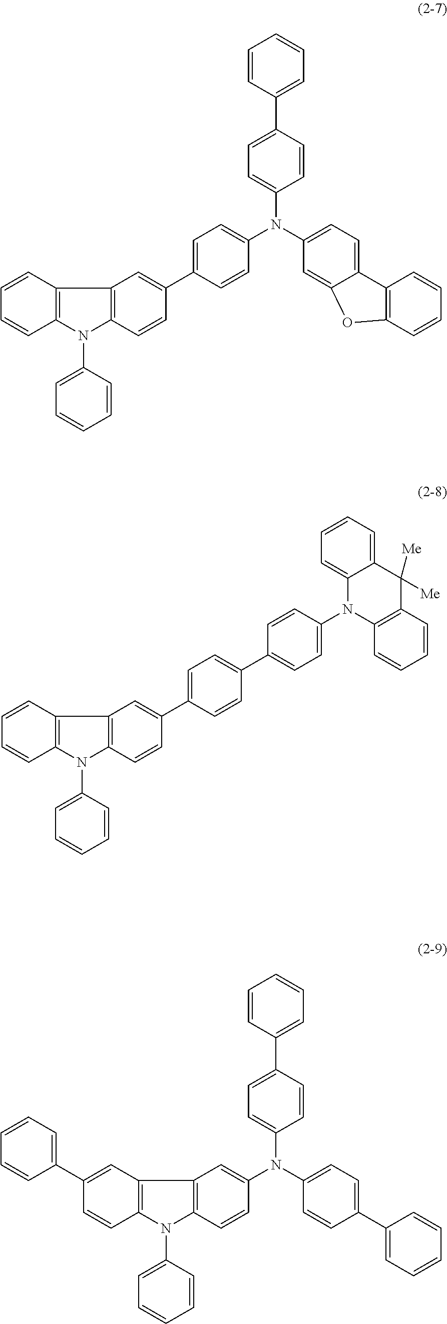

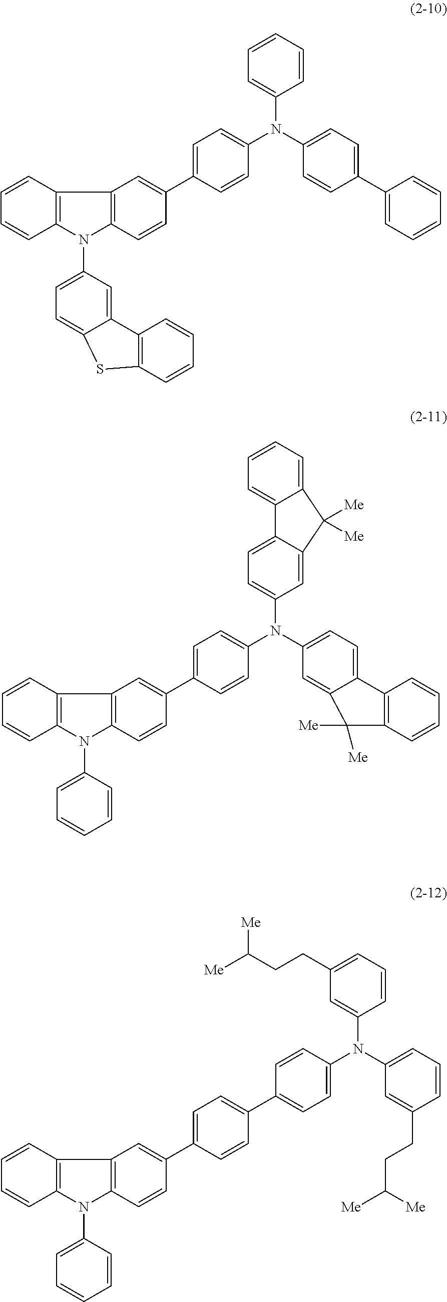

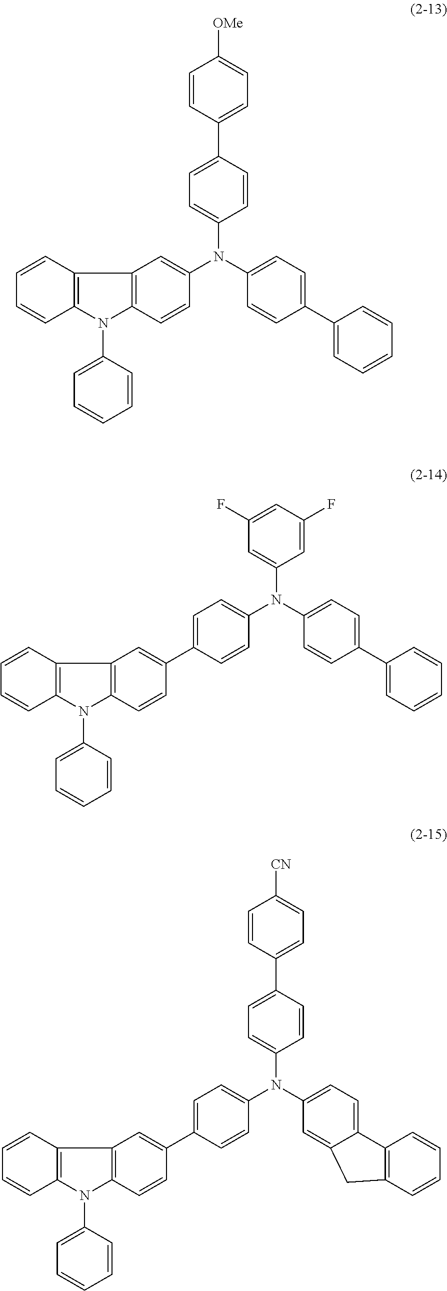

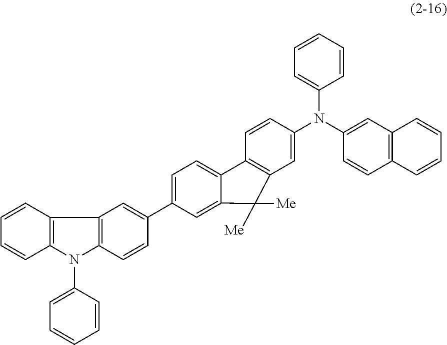

The intermediate hole transport material layer 133 may include the compound represented by the above General Formula (2) as the intermediate hole transport material. The intermediate hole transport material layer 133 may improve the hole transporting property of the hole transport layer 130, and may decrease the driving voltage of the organic electroluminescent device 100.

The compound represented by General Formula (2) may be included in the anode-side hole transport layer 131 as the anode-side hole transport material. In the case that the anode-side hole transport layer 131 includes the compound represented by General Formula (2) as the anode-side hole transport material, the hole transporting property of the hole transport layer 130 may be improved, and the driving voltage of the organic electroluminescent device 100 may be decreased.

In addition, the anode-side hole transport layer 131 may further include other hole transport materials as the anode-side hole transport material in addition to the compound represented by General Formula (2).

(1-1-4-3. Configuration of Emission Layer-Side Hole Transport Layer)

The emission layer-side hole transport layer 135 may include a compound represented by the following General Formula (1). The emission layer-side hole transport layer 135 may be formed, for example, on the intermediate hole transport material layer 133, adjacent to the emission layer 140.

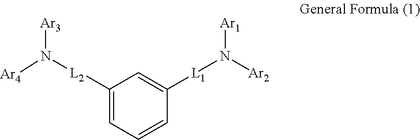

In the above General Formula (1), Ar₁, Ar₂, Ar₃, and Ar₄ may each independently be a substituted or unsubstituted aryl group having 6 to 50 ring carbon atoms or a substituted or unsubstituted heteroaryl group having 5 to 50 ring carbon atoms, and L₁ and L₂ are each independently a direct linkage, a substituted or unsubstituted arylene group having 6 to 18 ring carbon atoms or a substituted or unsubstituted heteroarylene group having 5 to 15 ring carbon atoms.

Examples of Ar₁, Ar₂, Ar₃, and Ar₄ may include a phenyl group, a biphenyl group, a terphenyl group, a naphthyl group, an anthryl group, a phenanthryl group, a fluorenyl group, an indenyl group, a pyrenyl group, an acetonaphthenyl group, a fluoranthenyl group, a triphenylenyl group, a pyridyl group, a furanyl group, a pyranyl group, a thienyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a pyrazolyl group, a dibenzofuranyl group, a dibenzothienyl group, etc. Examples of Ar₁-Ar₄ may include the phenyl group, the biphenyl group, the terphenyl group, the fluorenyl group, the carbazolyl group, the dibenzofuranyl group, etc.

Examples of L₁ and L₂ other than the direct linkage may include a substituent illustrated in the above Ar₁, Ar₂, Ar₃, and Ar₄, except in the form of a divalent substituent. Examples of L₁ and L₂, other than the direct linkage, may include the phenylene group, the naphthalene group, the biphenylylene group, the thienothiophenylene group and the pyridylene group. For example, L₁ and L₂ may be the direct linkage, the phenylene group or the biphenylylene group.

Examples of the compound represented by General Formula (1) may include the following Compounds 1-1 to 1-26.

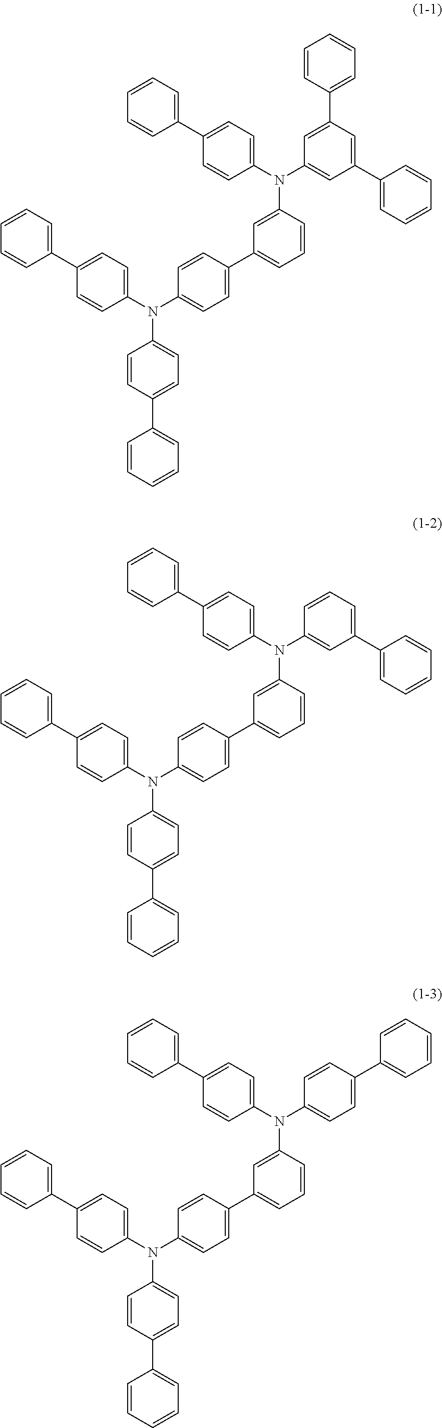

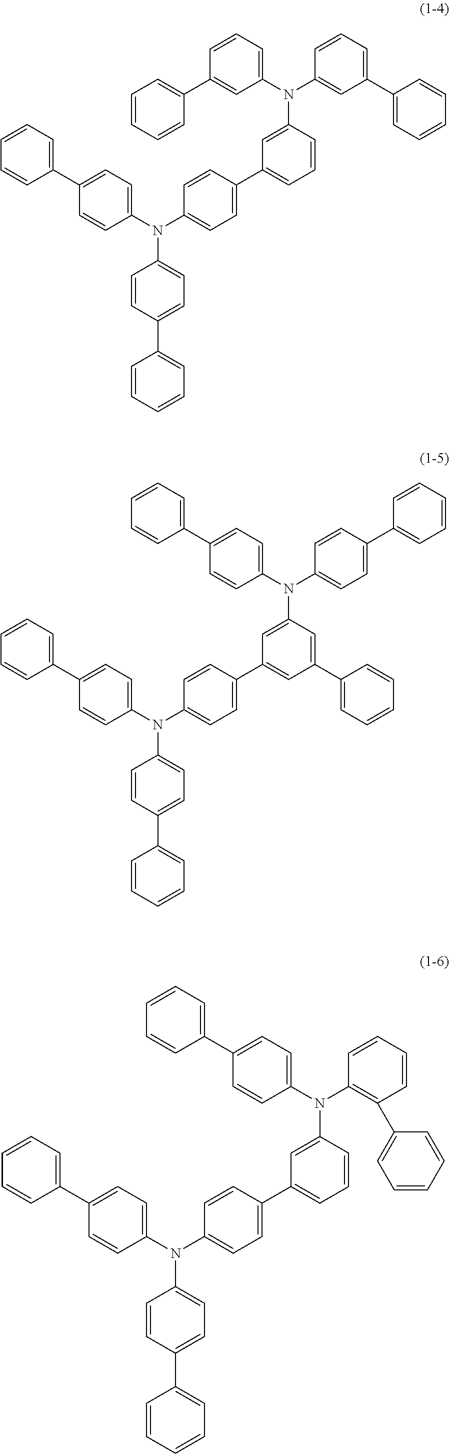

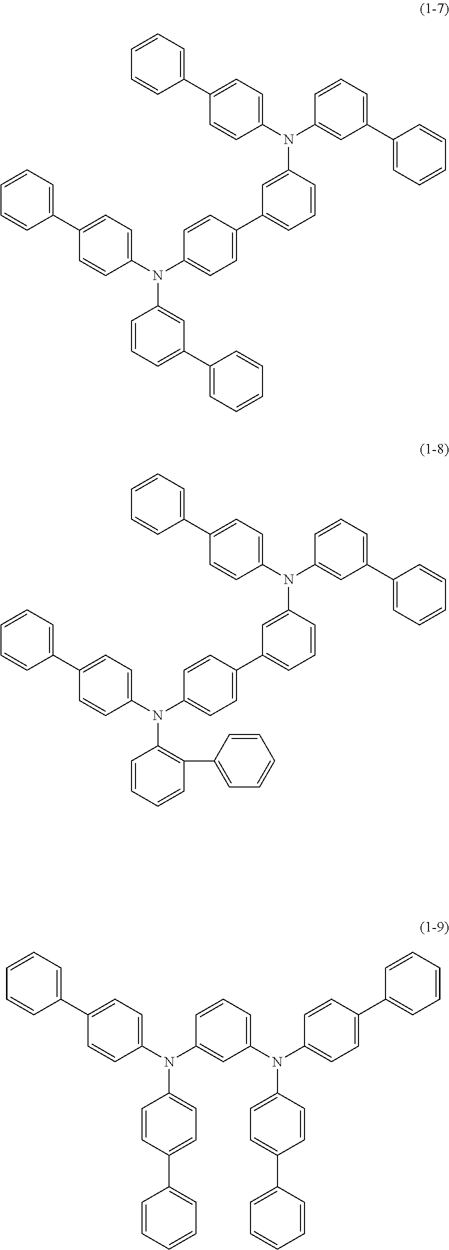

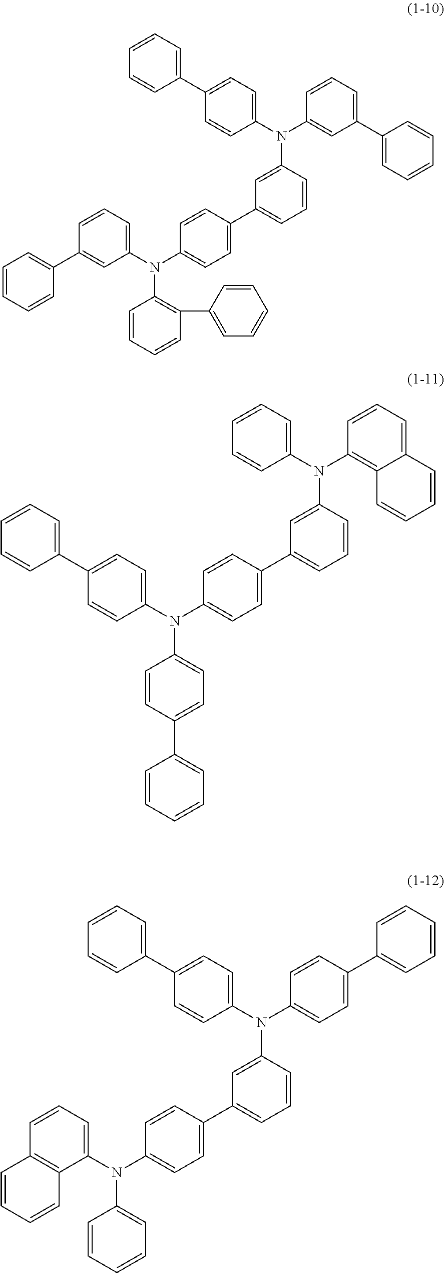

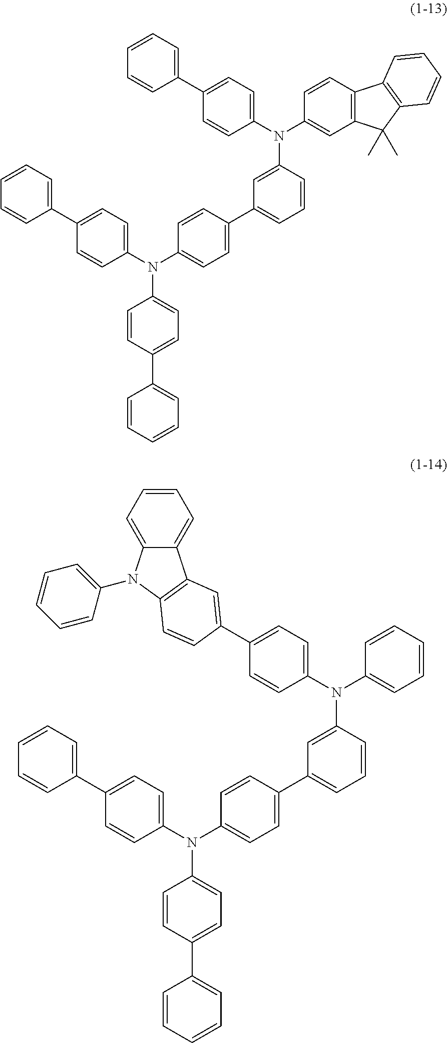

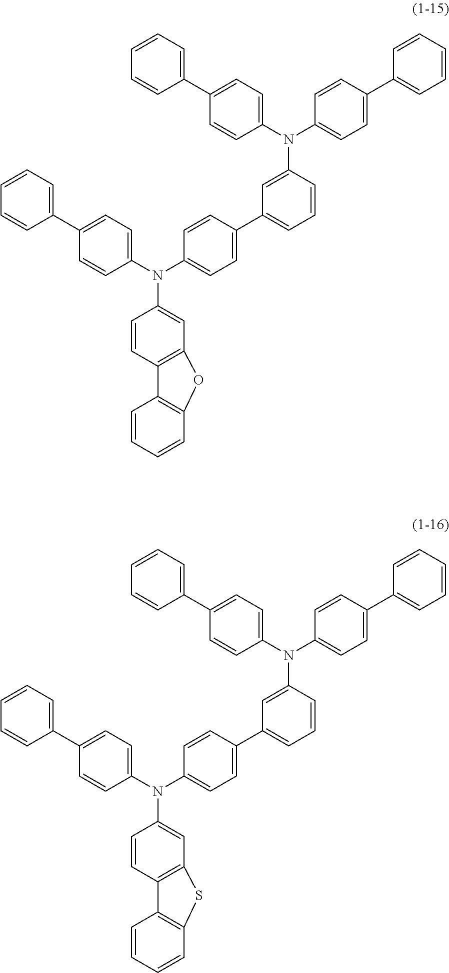

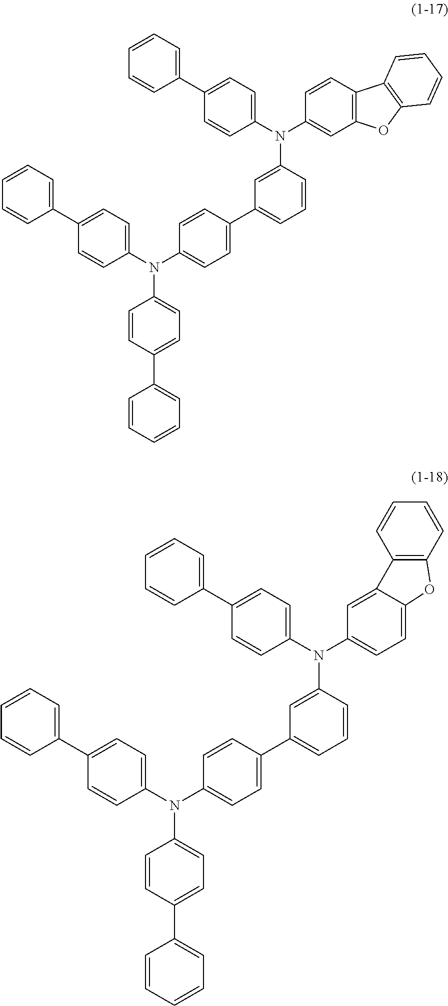

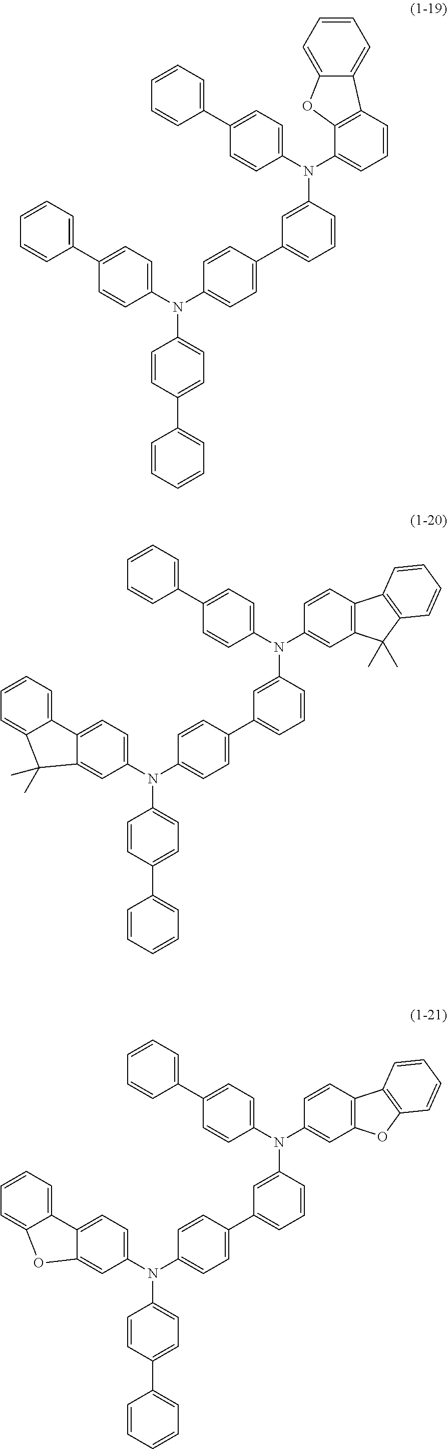

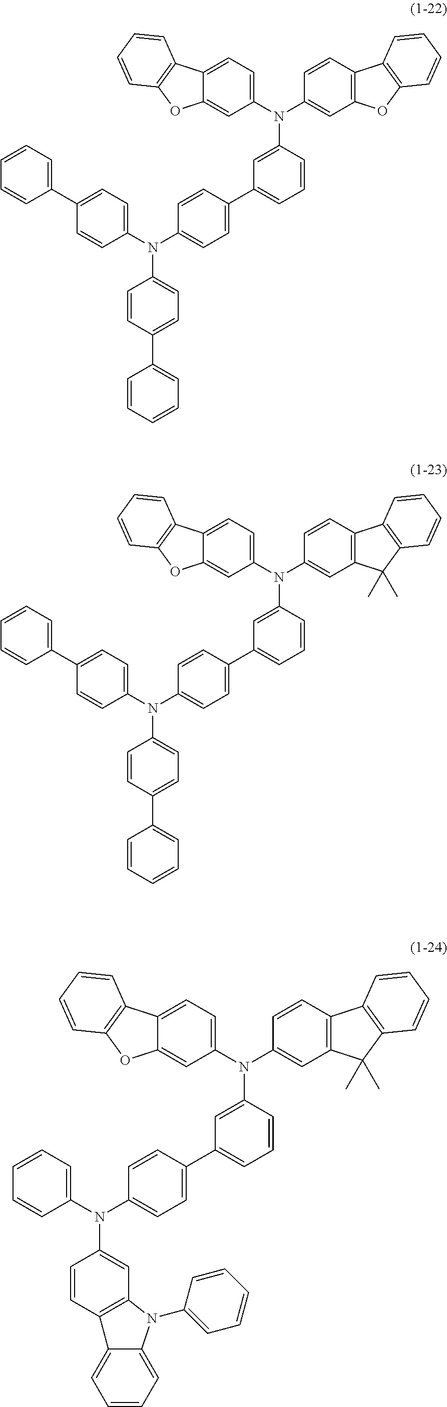

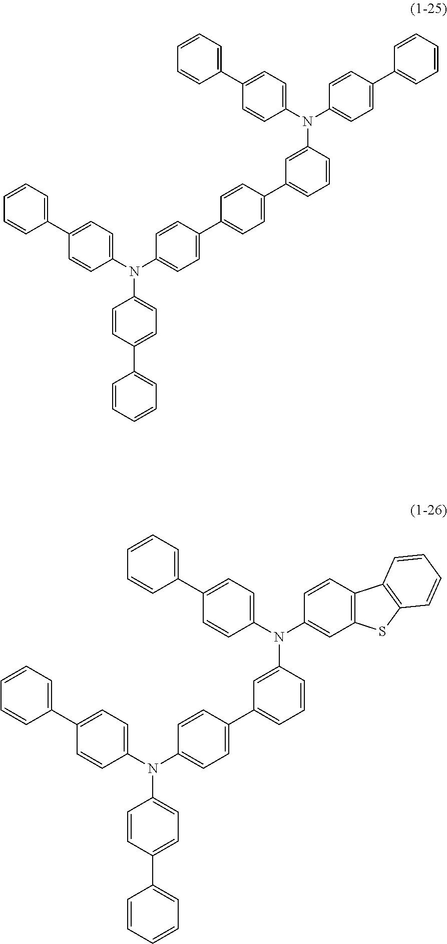

The emission layer-side hole transport layer 135 may include the compound represented by the above General Formula (1) as the emission layer-side hole transport material. The emission layer-side hole transport layer 135 may protect the hole transport layer 130 from electrons not consumed in the emission layer 140. When the emission layer-side hole transport layer 135 includes the compound represented by the above General Formula (1), the diffusion of the energy of an excited state generated in the emission layer 140 to the hole transport layer 130 may be reduced or prevented. Thus, according to this configuration, the emission layer-side hole transport layer 135 may improve the current flow durability of the hole transport layer 130.

The emission layer-side hole transport layer 135 may be formed near the emission layer 140 and, for example, may be formed adjacent to the emission layer 140 to effectively help prevent the diffusion of electrons or energy from the emission layer 140.

When the emission layer-side hole transport layer 135 includes the compound represented by the above General Formula (1), the charge balance of the whole organic electroluminescent device 100 may be controlled, and the diffusion of the electron accepting material doped into the anode-side hole transport layer 131 into the emission layer 140 may be restrained. Accordingly, the emission layer-side hole transport layer 135 may improve the charge transport property of the entire hole transport layer 130.

When the emission layer-side hole transport layer 135 includes the compound represented by the above General Formula (1), the charge transport property and current flow durability of the hole transport layer 130 may be improved, thereby decreasing the driving voltage of the organic electroluminescent device 100 and improving the emission life thereof.

As described above, the hole transport layer 130 including the anode-side hole transport layer 131, the intermediate hole transport material layer 133 and the emission layer-side hole transport layer 135 may improve the current flow durability and hole transport property of the organic electroluminescent device 100. Thus, the organic electroluminescent device 100 according to an embodiment may have a decreased driving voltage and improved emission life.

### 1-1-5. Configuration of Emission Layer

The emission layer 140 may include a host material, and a dopant material as a luminescent material, etc. The emission layer 140 may emit light via fluorescence or phosphorescence. The emission layer 140 may be formed, for example, on the hole transport layer 130 to a layer thickness from about 10 nm to about 60 nm.

The host material and the dopant material included in the emission layer 140 may include suitable host material and dopant material for an emission layer. For example, the emission layer 140 may include a fluoranthene derivative, a pyrene derivative, an arylacetylene derivative, a fluorene derivative, a perylene derivative, a chrysene derivative, etc. as the host material or the dopant material. For example, the emission layer 140 may include tris(-quinolinolato)aluminum (Alq3), 4,4′-N,N′-dicarbazole-biphenyl (CBP), poly(n-vinylcarbazole) (PVK), TCTA, 1,3,5-tris(N-phenylbenzimidazole-2-yl)benzene 3-tert-butyl-9,10-di(naphtho-2-yl)anthracene (TBADN), distyrylarylene (DSA), 4,4′-bis(9-carbazole)-2,2′-dimethyl-biphenyl (dmCBP), bis(2,2-diphenyl vinyl)-1,1′-biphenyl (DPVBi), 1,4-bis[2-(3-N-ethylcarbazolyl)vinyl]benzene (BCzVB), 4-(di-p-tolylamino)-4′-[(di-p-tolylamino)styryl]stilbene (DPAVB), N-(4-(E)-2-(6-((E)-4-(diphenylamino)styryl)naphthalen-2-yl)vinyl)phenyl)-N-phenylbenzenamine (N-BDAVBi), 2,5,8,11-tetra-t-butylperylene (TBPe), 1,1-dipyrene, 1,4-dipyrenylbenzene, 1,4-bis(N,N-diphenylamino)pyrene, etc. as the host material or the dopant material.

The improving effects of the current flow durability and hole transporting property of the hole transport layer 130 may be even further markedly shown when the emission layer 140 mainly includes a luminescent material that emits light via a singlet excited state (that is, that emits light via fluorescence). The emission layer 140 may include a fluorescent dopant material and may emit light mainly by fluorescence.

In addition, the emission layer 140 may include a compound represented by the following General Formula (3).

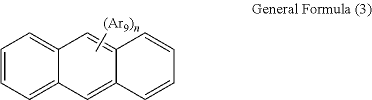

In the above General Formula (3), each Ar₉ is independently a hydrogen atom, a deuterium atom, a substituted or unsubstituted alkyl group having 1 to 50 carbon atoms, a substituted or unsubstituted cycloalkyl group having 3 to 50 ring carbon atoms, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 ring carbon atoms, a substituted or unsubstituted arylthio group having 6 to 50 ring carbon atoms, a substituted or unsubstituted alkoxycarbonyl group having 2 to 50 carbon atoms, a substituted or unsubstituted aryl group having 6 to 50 ring carbon atoms, a substituted or unsubstituted heteroaryl group having 5 to 50 ring carbon atoms, a substituted or unsubstituted silyl group, a carboxyl group, a halogen atom, a cyano group, a nitro group or a hydroxyl group, and n is an integer from 1 to 10.

Examples of the compound represented by General Formula (3) may include the following Compounds 3-1 to 3-12.

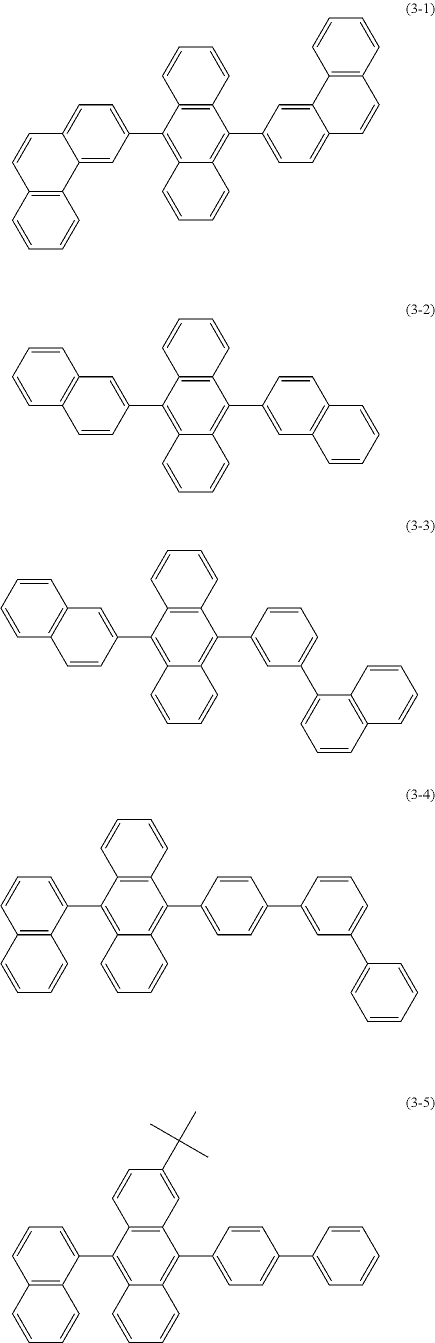

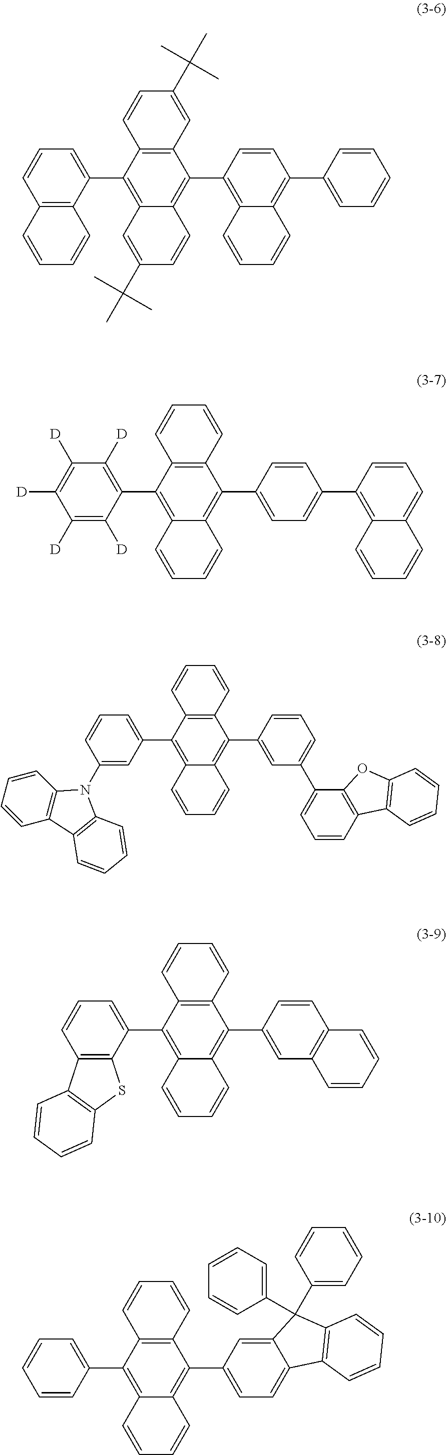

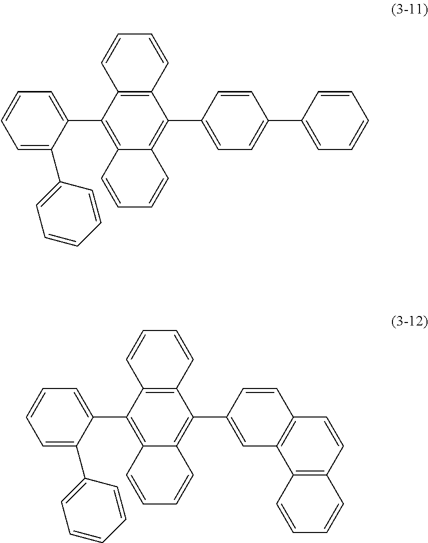

In the case that the emission layer 140 includes the compound represented by General Formula (3), the anode-side hole transport layer 131 may improve the hole injection property from the first electrode 120 even further. The emission layer 140 may further improve the emission property of the organic electroluminescent device 100 by including the compound represented by General Formula (3).

In addition, the emission layer 140 may include the compound represented by General Formula (3) as the host material or as the dopant material.

The emission layer 140 may be formed as an emission layer that emits light with a specific color. For example, the emission layer 140 may be formed as a red emitting layer, a green emitting layer or a blue emitting layer.

When the emission layer 140 is the blue emitting layer, suitable a blue dopant may be used. For example, perylene or a derivative thereof, an iridium (Ir) complex such as bis[2-(4,6-difluorophenyl)pyridinate]picolinate iridium(III) (FIrpic), etc. may be used as a blue dopant.

When the emission layer 140 is the red emitting layer, suitable a red dopant may be used. For example, rubrene or a derivative thereof, 4-dicyanomethylene-2-(p-dimethylaminostyryl)-6-methyl-4H-pyrane (DCM) or a derivative thereof, an iridium complex such as bis(1-phenylisoquinoline)(acetylacetonate) iridium(III) (Ir(piq)₂(acac), an osmium (Os) complex, a platinum complex, etc. may be used as the red dopant.

When the emission layer 140 is the green emitting layer, a suitable green dopant may be used. For example, coumarin or a derivative thereof, an iridium complex such as tris(2-phenylpyridine) iridium(III) (Ir(ppy)₃), etc. may be used.

### 1-1-6. Configuration of Electron Transport Layer

The electron transport layer 150 may be a layer including an electron transport material and having electron transporting function. The electron transport layer 150 may be formed, for example, on the emission layer 150 to a layer thickness from about 15 nm to about 50 nm. The electron transport material included in the electron transport layer 150 may be a suitable electron transport material. Examples of the electron transport material may include, e.g. Alq3, a material having a nitrogen-containing aromatic ring (a material including a pyridine ring such as 1,3,5-tri[(3-pyridyl)-phen-3-yl]benzene, a material including a triazine ring such as 2,4,6-tris(3′(pyridine-3-yl)biphenyl-2-yl)-1,3,5-triazine, a material including an imidazole derivative such as 2-(4-(N-phenylbenzoimidazolyl-1-ylphenyl)-9,10-dinaphthylanthracene), etc.

### 1-1-7. Configuration of Electron Injection Layer

The electron injection layer 160 may be a layer having function of facilitating injection of electrons from the second electrode 170. The electron injection layer 160 may be formed, for example, on the electron transport layer 150 to a layer thickness from about 0.3 nm to about 9 nm. The electron injection layer 160 may a suitable material for forming the electron injection layer 160. Examples for forming the electron injection layer 160 may include a Li complex such as lithium 8-quinolinato (Liq), lithium fluoride (LiF), etc., sodium chloride (NaCl), cesium fluoride (CsF), lithium oxide (Li₂O), barium oxide (BaO), etc.

### 1-1-8. Configuration of Second Electrode

The second electrode 170 may be, for example, a cathode. The second electrode 170 may be formed on the electron injection layer 160 using an evaporation method or a sputtering method. The second electrode 170 may be formed as a reflection type electrode using a metal, an alloy, a conductive compound, etc. having small work function. The second electrode 170 may be formed using, e.g. a metal such as lithium (Li), magnesium (Mg), aluminum (Al), calcium (Ca), etc., a mixture of metals such as aluminum-lithium (Al—Li), magnesium-indium (Mg—In), magnesium-silver (Mg—Ag), etc. In some implementations, the second electrode 170 may be formed as a transmission type electrode using ITO, IZO, etc.

### 1-1-9. Modification Example of Organic Electroluminescent Device

The structure of the organic electroluminescent device 100 illustrated in FIG. 1 is provided as an example. In the organic electroluminescent device 100 according to an embodiment, some layers may be formed as multi-layers, or other layers may be additionally formed. In addition, in the organic electroluminescent device 100 according to an embodiment, at least one of the electron transport layer 150 and the electron injection layer 160 may be omitted.

In the organic electroluminescent device 100 according to an embodiment, a hole injection layer may be provided between the first electrode 120 and the hole transport layer 130.

The hole injection layer may be a layer having function of facilitating the injection of holes from the first electrode 120. The hole injection layer may be formed on the first electrode 120 to a layer thickness from, for example, about 10 nm to about 150 nm. The hole injection layer may be formed using a suitable material for forming the hole injection layer. Examples of the material for forming the hole injection layer may include a triphenylamine-containing polyether ketone (TPAPEK), 4-isopropyl-4′-methyldiphenyliodonium tetrakis(pentafluorophenyl)borate (PPBI), N,N′-diphenyl-N,N′-bis-[4-(phenyl-m-tolyl-amino)-phenyl]-biphenyl-4,4′-diamine (DNTPD), a phthalocyanine compound such as copper phthalocyanine, etc., 4,4′,4″-tris(3-methylphenylphenylamino)triphenylamine (m-MTDATA), N,N′-di(1-naphthyl)-N,N′-diphenylbenzidine (NPB), 4,4′,4″-tris{N,N-diphenylamino}triphenylamine (TDATA), 4,4′4″-tris(N,N-2-naphthylphenylamino)triphenylamine (2-TNATA), polyaniline/dodecylbenzenesulfonic acid (Pani/DBSA), poly(3,4-ethylenedioxythiophene)/poly(4-styrenesulfonate) (PEDOT/PSS), polyaniline/camphorsulfonic acid (Pani/CSA) or polyaniline/poly(4-styrenesulfonate (PANI/PSS), etc.

### 1-1-9. Method of Manufacturing Organic Electroluminescent Device

Each layer of the organic electroluminescent device 100 according to an embodiment as described above may be formed by selecting an appropriate layer forming method according to materials such as vacuum evaporation, sputtering, various coating methods, etc.

For example, a metal layer such as the first electrode 120, the second electrode 170, the electron injection layer 160, etc. may be formed using an evaporation method including an electron beam evaporation method, a hot filament evaporation method, a vacuum evaporation method, a sputtering method, or a plating method such as an electroplating method or an electroless plating method.

An organic layer such as the hole transport layer 130, the emission layer 140 and the electron transport layer 150 may be formed using a physical vapor deposition (PVD) method such as a vacuum deposition method, a printing method such as a screen printing method or an ink jet printing method, a laser transcription method or a coating method such as a spin coating method.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

Hereinabove, an embodiment of the organic electroluminescent device 100 according to an embodiment has been explained in detail.

### 1-2. Examples

### 1-2-1. Manufacture of Organic Electroluminescent Device Including Anode-Side Hole Transport Material and Anode-Side Hole Transport Layer Doped with Electron Accepting Material

An organic electroluminescent device according to an embodiment was manufactured by the following manufacturing method.

First, with respect to an ITO-glass substrate patterned and washed in advance, surface treatment using UV-Ozone (O₃) was conducted. The layer thickness of an ITO layer (first electrode) on the glass substrate was about 150 nm. After ozone treatment, the substrate was washed and inserted in a glass bell jar type evaporator for forming an organic layer. An anode-side hole transport layer, an intermediate hole transport material layer, an emission layer-side hole transport layer, an emission layer, and an electron transport layer were evaporated one by one with a vacuum degree of about 10⁻⁴ to about 10⁻⁵ Pa. The layer thickness of each of the anode-side hole transport layer, the intermediate hole transport material layer and the emission layer-side hole transport layer was about 10 nm. The layer thickness of the emission layer was about 25 nm, and the layer thickness of the electron transport layer was about 25 nm. Then, the substrate was moved into a glass bell jar type evaporator for forming a metal layer, and the electron injection layer and the second electrode were evaporated with a vacuum degree of about 10⁻⁴ to about 10⁻⁵ Pa. The layer thickness of the electron injection layer was about 1 nm, and the layer thickness of the second electrode was about 100 nm.

The anode-side hole transport layer, the intermediate hole transport material layer, and the emission layer-side hole transport layer correspond to the hole transport layer with a stacked structure. The anode-side hole transport layer, the intermediate hole transport material layer, and the emission layer-side hole transport layer were manufactured in examples and comparative examples using the materials shown in the following Table 1.

In addition, e.g. the expression of “Compound 1-3, 4-15” in Table 1 indicates that Compound 1 is the anode-side hole transport material, and Compound 4-15 is the doped electron accepting material. The amount doped of the electron accepting material was about 3 wt % on the basis of the amount of the anode-side hole transport material.

Compounds 6-1, 6-2 and 6-3 refer to common hole transport materials represented by the following formulae.

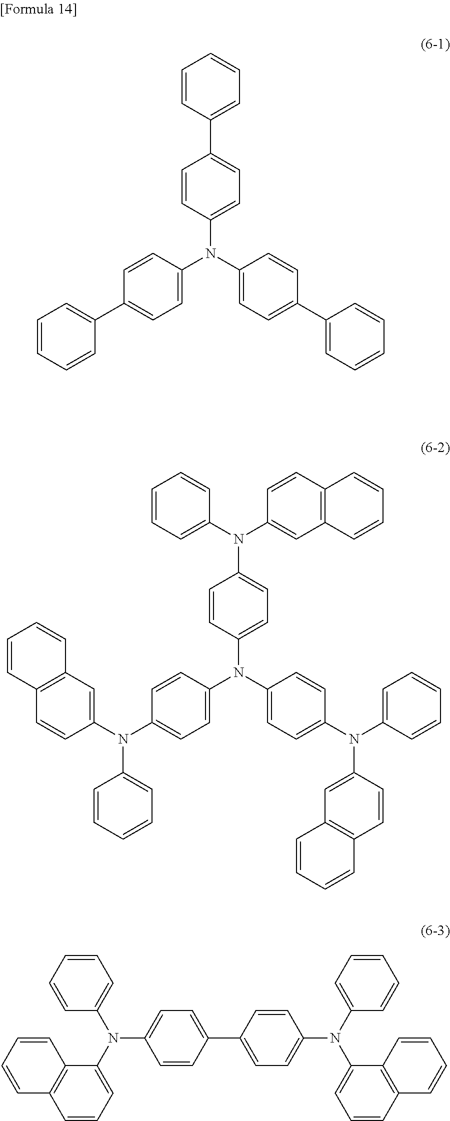 [SMILES: c1ccc(-c2ccc(N(c3ccc(-c4ccccc4)cc3)c3ccc(-c4ccccc4)cc3)cc2)cc1 ; c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1 ; c1ccc(N(c2ccc(-c3ccc(N(c4ccccc4)c4cccc5ccccc45)cc3)cc2)c2cccc3ccccc23)cc1]

As the host material of the emission layer, 9,10-di(2-naphthyl)anthracene (ADN, Compound 3-2) was used, and as the dopant material, 2,5,8,11-tetra-t-butylpherylene (TBP) was used. In addition, the dopant material was added in an amount of about 3 wt % on the basis of the amount of the host material. The electron transport layer was formed using Alq3, the electron injection layer was formed using LiF, and the second electrode was formed using aluminum (Al).

### 1-2-2. Evaluation Results

The driving voltage and the emission life of the organic electroluminescent device thus manufactured were evaluated. The evaluation results are shown together in the following Table 1. In addition, the half life of examples and comparative examples were obtained by measuring with current density of about 10 mA/cm² and initial luminance of about 1,000 cd/m², and the half life in Table 1 is shown as a relative ratio with the half life of Comparative Example 1-1 as being 1.

In addition, the measurement was conducted using a source meter of 2400 series of Keithley Instruments Co., Color brightness photometer CS-200 (Konica Minolta holdings, measurement angle of 1°), and a PC program LabVIEW8.2 (National instruments in Japan) for measurement in a dark room.

TABLE 1

| | | Intermediate | Emission layer- | | |
|---|---|---|---|---|---|
| | Anode-side hole | hole transport | side hole | Driving | Emission |
| | transport layer | material layer | transport layer | voltage [V] | life |
| Example 1-1 | Compound 2-3, | Compound 2-3 | Compound 1-3 | 6.2 | 1.55 |
| | Compound 4-15 | | | | |
| Example 1-2 | Compound 6-2, | Compound 2-3 | Compound 1-3 | 6.3 | 1.41 |
| | Compound 4-15 | | | | |
| Example 1-3 | Compound 2-3, | Compound 6-3 | Compound 1-3 | 6.3 | 1.22 |
| | Compound 4-15 | | | | |
| Comparative | Compound 2-3 | Compound 2-3 | Compound 1-3 | 7.4 | 1.00 |
| Example 1-1 | | | | | |
| Comparative | Compound 2-3, | Compound 1-3 | Compound 2-3 | 6.5 | 0.92 |
| Example 1-2 | Compound 4-15 | | | | |
| Comparative | Compound 2-3, | Compound 2-3 | Compound 6-1 | 6.4 | 0.94 |
| Example 1-3 | Compound 4-15 | | | | |

Referring to the results in Table 1, it can be seen that the driving voltage was decreased, and the emission life was increased for the organic electroluminescent devices of Examples 1-1 to 1-3 when compared to those of Comparative Examples 1-1 to 1-3. Thus, it can be seen that the driving voltage was decreased and the emission life was increased for the organic electroluminescent device by providing the anode-side hole transport layer, the intermediate hole transport material layer and the emission layer-side hole transport layer between the first electrode and the emission layer.

When comparing Example 1-1 with Comparative Example 1-1, it can be seen that the properties of Example 1-1 were good. In Comparative Example 1-1, the electron accepting material, Compound 4-15 was not doped into the anode-side hole transport layer. It can be seen that the anode-side hole transport layer doped with the electron accepting material was provided a decreased driving voltage and superior emission life.

When comparing Example 1-1 with Comparative Example 1-2, it can be seen that the properties of Example 1-1 were good. In Comparative Example 1-2, the compounds included in the intermediate hole transport material layer and the emission layer-side hole transport layer were changed when compared to those in Example 1-1. Thus, it can be seen that the emission layer-side hole transport layer including the compound represented by General Formula (1) adjacent to the emission layer provided a decreased driving voltage and superior emission life.

When comparing Example 1-1 with Comparative Example 1-3, it can be seen that the properties of Example 1-1 were good. In Comparative Example 1-3, in the emission layer-side hole transport material included in the emission layer-side hole transport layer, a common hole transport material, Compound 6-1 was used instead of Compound 1-3 represented by General Formula (1). Thus, it can be seen that the inclusion of the compound represented by General Formula (1) in the emission layer-side hole transport layer provided a decreased driving voltage and superior emission life.

When comparing Example 1-1 with Example 1-2, the properties of Example 1-1 were good. In Example 1-2, in the anode-side hole transport material included in the anode-side hole transport layer, a common hole transport material, Compound 6-2 was used instead of Compound 2-3 represented by General Formula (2). Thus, it can be seen that the inclusion of the compound represented by General Formula (2) in the anode-side hole transport layer provided a decreased driving voltage and superior emission life.

In addition, when comparing Example 1-1 with Example 1-3, the properties of Example 1-1 were good. In Example 1-3, in the intermediate hole transport material included in the intermediate hole transport material layer, a common hole transport material, Compound 6-3 was used instead of Compound 2-3 represented by General Formula (2). Thus, it can be seen that the inclusion of the compound represented by General Formula (2) in the intermediate hole transport material layer provided a decreased driving voltage and superior emission life.

As described above, according to exemplary embodiments, when the anode-side hole transport layer doped with the electron accepting material, the intermediate hole transport material layer and the emission layer-side hole transport layer including the compound represented by General Formula (1) were stacked between the first electrode (anode) and the emission layer, the driving voltage of the organic electroluminescent device may be decreased, and the emission life thereof may be increased.

By disposing the emission layer-side hole transport layer including the compound represented by General Formula (1), the emission layer-side hole transport layer may protect the hole transport layer from electrons not consumed in the emission layer and may help prevent the diffusion of excited state energy generated in the emission layer into the hole transport layer, thereby controlling the charge balance of the whole device. In addition, by disposing the emission layer-side hole transport layer including the compound represented by General Formula (1), the emission layer-side hole transport layer may restrain the diffusion of the electron accepting material included in the anode-side hole transport layer provided near the first electrode (anode) into the emission layer.

### 2-1. Configuration of Organic Electroluminescent Device Including Anode-Side Hole Transport Layer Including Mainly Electron Accepting Material

Hereinafter, an organic electroluminescent device including an anode-side hole transport layer including mainly an electron accepting material will be explained referring to FIG. 1.

The organic electroluminescent device including the anode-side hole transport layer including mainly the electron accepting material may include the above-mentioned anode-side hole transport material and may have the same overall configuration of the organic electroluminescent device including the hole anode-side hole transport layer doped with the electron accepting material, the substrate, the first electrode, the emission layer, the electron transport layer, the electron injection layer, the second electrode and method of manufacturing the organic electroluminescent device, and may have a different configuration of the hole transport layer. Thus, the configuration of the hole transport layer will be explained particularly, hereinafter.

### 2-1-1. Configuration of Hole Transport Layer

The hole transport layer 130 may include a hole transport material and may have hole transporting function. The hole transport layer 130 may be formed, for example, on the first electrode 120 to a layer thickness (total layer thickness of a stacked structure) of about 10 nm to about 150 nm.

The hole transport layer 130 of the organic electroluminescent device 100 according to an embodiment may be formed as a multi-layer by stacking from the first electrode 120, an anode-side hole transport layer 131, an intermediate hole transport material layer 133 and an emission layer-side hole transport layer 135 one by one.

(2-1-1-1. Configuration of Anode-Side Hole Transport Layer)

The anode-side hole transport layer 131 may be a layer including mainly an electron accepting material. For example, the anode-side hole transport layer 131 may be formed on the first electrode 120.

The anode-side hole transport layer 131 may be a layer formed using mainly the electron accepting material, and a material other than the electron accepting material may be included. The expression of “the anode-side hole transport layer 131 may be formed using mainly the electron accepting material” indicates that the anode-side hole transport layer 131 includes about 50 wt % or more of the electron accepting material on the basis of the total amount of the anode-side hole transport layer 131.

The anode-side hole transport layer 131 may be formed using mainly the electron accepting material. The anode-side hole transport layer 131 may improve the hole injection from the first electrode 120. Thus, the anode-side hole transport layer 131 may be provided near the first electrode 120, for example, adjacent to the first electrode 120.

The electron accepting material included in the anode-side hole transport layer 131 may be a suitable electron accepting material. The electron accepting material included in the anode-side hole transport layer 131 may have a LUMO level from about −9.0 eV to about −4.0 eV, or, for example, a LUMO level from about −6.0 eV to about −4.0 eV.

Examples of the electron accepting material having the LUMO level from about −9.0 eV to about −4.0 eV may include the compounds represented by the following Formulae 4-1 to 4-14.

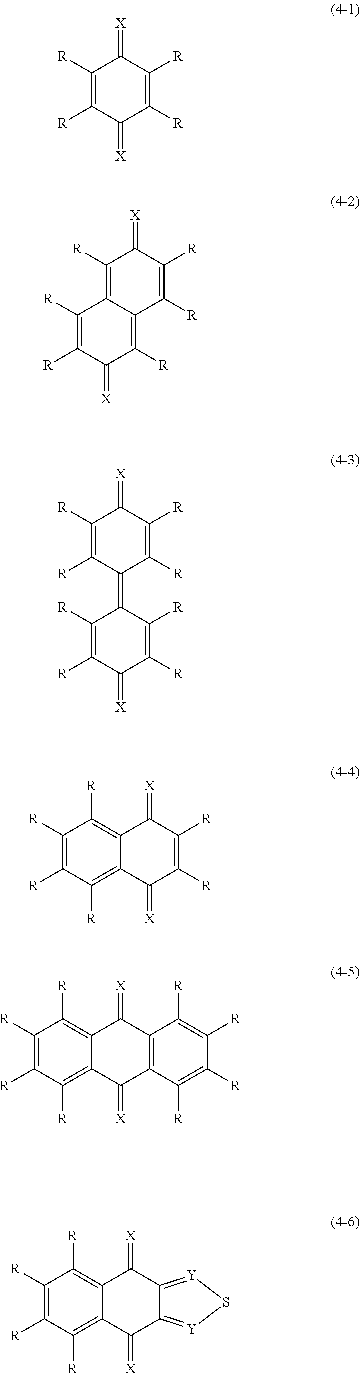

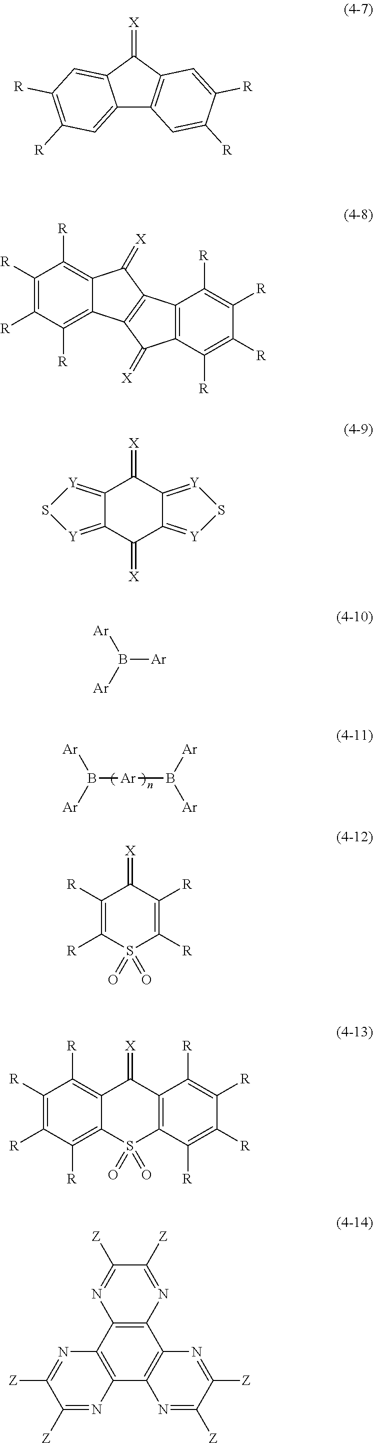

In the above Formulae 4-1 to 4-14, R is a hydrogen atom, a deuterium atom, a halogen atom, a fluoroalkyl group having 1 to 50 carbon atoms, a cyano group, an alkoxy group having 1 to 50 carbon atoms, an alkyl group having 1 to 50 carbon atoms, an aryl group having 6 to 50 carbon atoms or a heteroaryl group having 5 to 50 ring carbon atoms.

Ar is an aryl group having an electron withdrawing substituent or an unsubstituted aryl group having 6 to 50 ring carbon atoms or a substituted or unsubstituted heteroaryl group having 5 to 50 ring carbon atoms, Y is a methine group (—CH═) or a nitrogen atom (—N═), Z is a pseudohalogen atom or a sulfur (S) atom, n is an integer of 10 and less, and X is one of the substituents represented by the following formulae X1 to X7.

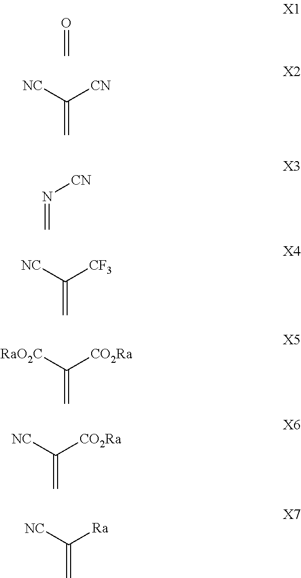

In the above Formulae X1 to X7, Ra is a hydrogen atom, a deuterium atom, a halogen atom, a fluoroalkyl group having 1 to 50 carbon atoms, a cyano group, an alkoxy group having 1 to 50 carbon atoms, an alkyl group having 1 to 50 carbon atoms, a substituted or unsubstituted aryl group having 6 to 50 ring carbon atoms or a substituted or unsubstituted heteroaryl group having 5 to 50 ring carbon atoms.

Examples of the substituted or unsubstituted aryl group having 6 to 50 ring carbon atoms represented by R, Ar and Ra may include a phenyl group, a 1-naphthyl group, a 2-naphthyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group, a 1-naphthacenyl group, a 2-naphthacenyl group, a 9-naphthacenyl group, a 1-pyrenyl group, a 2-pyrenyl group, a 4-pyrenyl group, a 2-biphenylyl group, a 3-biphenylyl group, a 4-biphenylyl group, a p-terphenyl-4-yl group, a p-terphenyl-3-yl group, a p-terphenyl-2-yl group, a m-terphenyl-4-yl group, a m-terphenyl-3-yl group, a m-terphenyl-2-yl group, an o-tolyl group, a m-tolyl group, a p-tolyl group, a p-t-butylphenyl group, a p-(2-phenylpropyl)phenyl group, a 3-methyl-2-naphthyl group, a 4-methyl-1-naphthyl group, a 4-methyl-1-anthryl group, a 4′-methylbiphenylyl group, a 4″-t-butyl-p-terphenyl-4-yl group, a fluoranthenyl group, a fluorenyl group, etc.

Examples of the substituted or unsubstituted heteroaryl group having 5 to 50 ring carbon atoms represented by R, Ar and Ra may include a 1-pyrrolyl group, a 2-pyrrolyl group, a 3-pyrrolyl group, a pyrazinyl group, a 2-pyridinyl group, a 3-pyridinyl group, a 4-pyridinyl group, a 1-indolyl group, a 2-indolyl group, a 3-indolyl group, a 4-indolyl group, a 5-indolyl group, a 6-indolyl group, a 7-indolyl group, a 1-isoindolyl group, a 2-isoindolyl group, a 3-isoindolyl group, a 4-isoindolyl group, a 5-isoindolyl group, a 6-isoindolyl group, a 7-isoindolyl group, a 2-furyl group, a 3-furyl group, a 2-benzofuranyl group, a 3-benzofuranyl group, a 4-benzofuranyl group, a 5-benzofuranyl group, a 6-benzofuranyl group, a 7-benzofuranyl group, a 1-isobenzofuranyl group, a 3-isobenzofuranyl group, a 4-isobenzofuranyl group, a 5-isobenzofuranyl group, a 6-isobenzofuranyl group, a 7-isobenzofuranyl group, a quinolyl group, a 3-quinolyl group, a 4-quinolyl group, a 5-quinolyl group, a 6-quinolyl group, a 7-quinolyl group, a 8-quinolyl group, a 1-isoquinolyl group, a 3-isoquinolyl group, a 4-isoquinolyl group, a 5-isoquinolyl group, a 6-isoquinolyl group, a 7-isoquinolyl group, a 8-isoquinolyl group, a 2-quinoxalinyl group, a 5-quinoxalinyl group, a 6-quinoxalinyl group, a 1-carbazolyl group, a 2-carbazolyl group, a 3-carbazolyl group, a 4-carbazolyl group, a 9-carbazolyl group, a 1-phenanthridinyl group, a 2-phenanthridinyl group, a 3-phenanthridinyl group, a 4-phenanthridinyl group, a 6-phenanthridinyl group, a 7-phenanthridinyl group, a 8-phenanthridinyl group, a 9-phenanthridinyl group, a 10-phenanthridinyl group, a 1-acridinyl group, a 2-acridinyl group, a 3-acridinyl group, a 4-acridinyl group, a 9-acridinyl group, a 1,7-phenanthroline-2-yl group, a 1,7-phenanthroline-3-yl group, a 1,7-phenanthroline-4-yl group, a 1,7-phenanthroline-5-yl group, a 1,7-phenanthroline-6-yl group, a 1,7-phenanthroline-8-yl group, a 1,7-phenanthroline-9-yl group, a 1,7-phenanthroline-10-yl group, a 1,8-phenanthroline-2-yl group, a 1,8-phenanthroline-3-yl group, a 1,8-phenanthroline-4-yl group, a 1,8-phenanthroline-5-yl group, a 1,9-phenanthroline-2-yl group, a 1,9-phenanthroline-3-yl group, a 1,9-phenanthroline-4-yl group, a 1,9-phenanthroline-5-yl group, a 1,9-phenanthroline-6-yl group, a 1,9-phenanthroline-7-yl group, a 1,9-phenanthroline-8-yl group, a 1,9-phenanthroline-10-yl group, a 1,10-phenanthroline-2-yl group, a 1,10-phenanthroline-3-yl group, a 1,10-phenanthroline-4-yl group, a 1,10-phenanthroline-5-yl group, a 2,9-phenanthroline-1-yl group, a 2,9-phenanthroline-3-yl group, a 2,9-phenanthroline-4-yl group, a 2,9-phenanthroline-5-yl group, a 2,9-phenanthroline-6-yl group, a 2,9-phenanthroline-7-yl group, a 2,9-phenanthroline-8-yl group, a 2,9-phenanthroline-10-yl group, a 2,8-phenanthroline-1-yl group, a 2,8-phenanthroline-3-yl group, a 2,8-phenanthroline-4-yl group, a 2,8-phenanthroline-5-yl group, a 2,8-phenanthroline-6-yl group, a 2,8-phenanthroline-7-yl group, a 2,8-phenanthroline-9-yl group, a 2,8-phenanthroline-10-yl group, a 2,7-phenanthroline-1-yl group, a 2,7-phenanthroline-3-yl group, a 2,7-phenanthroline-4-yl group, a 2,7-phenanthroline-5-yl group, a 2,7-phenanthroline-6-yl group, a 2,7-phenanthroline-8-yl group, a 2,7-phenanthroline-9-yl group, a 2,7-phenanthroline-10-yl group, a 1-phenazinyl group, a 2-phenazinyl group, a 1-phenothiazinyl group, a 2-phenothiazinyl group, a 3-phenothiazinyl group, a 4-phenothiazinyl group, a 10-phenothiazinyl group, a 1-fenoxaziny group, a 2-fenoxazinyl group, a 3-fenoxazinyl group, a 4-fenoxazinyl group, a 10-fenoxazinyl group, a 2-oxazolyl group, a 4-oxazolyl group, a 5-oxazolyl group, a 2-oxadiazolyl group, a 5-oxadiazolyl group, a 3-furazanyl group, a 2-thienyl group, a 3-thienyl group, a 2-methylpyrrole-1-yl group, a 2-methylpyrrole-3-yl group, a 2-methylpyrrole-4-yl group, a 2-methylpyrrole-5-yl group, a 3-methylpyrrole-1-yl group, a 3-methylpyrrole-2-yl group, a 3-methylpyrrole-4-yl group, a 3-methylpyrrole-5-yl group, a 2-t-butylpyrrole-4-yl group, a 3-(2-phenylpropyl)pyrrole-1-yl group, a 2-methyl-1-indolyl group, a 4-methyl-1-indolyl group, a 2-methyl-3-indolyl group, a 4-methyl-3-indolyl group, a 2-t-butyl-1-indolyl group, a 4-t-butyl-1-indolyl group, a 2-t-butyl-3-indolyl group, a 4-t-butyl-3-indolyl group, etc.

Examples of the fluoroalkyl group in the substituted or unsubstituted fluoroalkyl group having 1 to 50 carbon atoms represented by R and Ra may include a perfluoroalkyl group such as a trifluoromethyl group, a pentafluoroethyl group, a heptafluoropropyl group and a heptadecafluorooctane group, a monofluoromethyl group, a difluoromethyl group, a trifluoroethyl group, a tetrafluoropropyl group, an octafluoropentyl group, etc.

Examples of the substituted or unsubstituted alkyl group having 1 to 50 carbon atoms represented by R and Ra may include a methyl group, an ethyl group, a propyl group, an isopropyl group, a n-butyl group, a s-butyl group, an isobutyl group, a t-butyl group, a n-pentyl group, a n-hexyl group, a n-heptyl group, a n-octyl group, a hydroxymethyl group, a 1-hydroxyethyl group, a 2-hydroxyethyl group, a 2-hydroxyisobutyl group, a 1,2-dihydroxyethyl group, a 1,3-dihydroxyisopropyl group, a 2,3-dihydroxy-t-butyl group, a 1,2,3-trihydroxypropyl group, a chloromethyl group, a 1-chloroethyl group, a 2-chloroethyl group, a 2-chloroisobutyl group, a 1,2-dichloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 2-nitroisobutyl group, a 1,2-dinitroethyl group, a 1,3-dinitroisopropyl group, a 2,3-dinitro-t-butyl group, a 1,2,3-trinitropropyl group, a cyclopropyl group, a cyclobutyl group, a cyclopentyl group, a cyclohexyl group, a 4-methylcyclohexyl group, a 1-adamantyl group, a 2-adamantyl group, a 1-norbornyl group, a 2-norbornyl group, etc.

The substituted or unsubstituted alkoxy group having 1 to 50 carbon atoms represented by R and Ra may be a group represented by —OY. Examples of Y may include a methyl group, an ethyl group, a propyl group, an isopropyl group, a n-butyl group, a s-butyl group, an isobutyl group, a t-butyl group, a n-pentyl group, a n-hexyl group, a n-heptyl group, a n-octyl group, a hydroxymethyl group, a 1-hydroxyethyl group, a 2-hydroxyethyl group, a 2-hydroxyisobutyl group, a 1,2-dihydroxyethyl group, a 1,3-dihydroxyisopropyl group, a 2,3-dihydroxy-t-butyl group, a 1,2,3-trihydroxypropyl group, a chloromethyl group, a 1-chloroethyl group, a 2-chloroethyl group, a 2-chloroisobutyl group, a 1,2-chloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 2-nitroisobutyl group, a 1,2-dinitroethyl group, a 1,3-dinitroisopropyl group, a 2,3-dinitro-t-butyl group, a 1,2,3-trinitropropyl group, etc.

Examples of the halogen atom represented by R and Ra may include fluorine (F), chlorine (CO, bromine (Br), iodine (I), etc.

Examples of compounds of the electron accepting material may include the following Compounds 4-15 and 4-16. For example, the LUMO level of Compound 4-15 may be about −4.40 eV, and the LUMO level of Compound 4-16 may be about −5.20 eV.

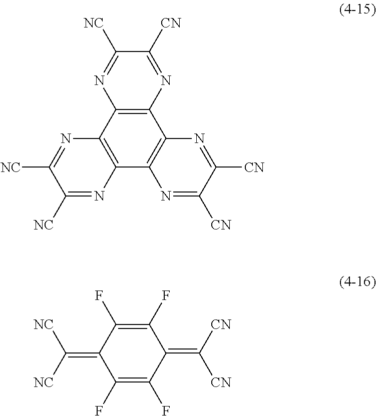 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F]

(2-1-1-2. Configuration of Intermediate Hole Transport Material Layer)

The intermediate hole transport material layer 133 may include an intermediate hole transport material. The intermediate hole transport material layer 133 may be formed on, for example, the anode-side hole transport layer 131.

The anode-side hole transport material included in the anode-side hole transport layer 131 may be a suitable hole transport material. Examples of the intermediate hole transport material included in the intermediate hole transport layer 133 may include TAPC, a carbazole derivative such as N-phenyl carbazole, polyvinyl carbazole, etc., TPD, TCTA, NPB, etc.

In some implementations, the intermediate hole transport material may be a compound represented by the following General Formula (2).

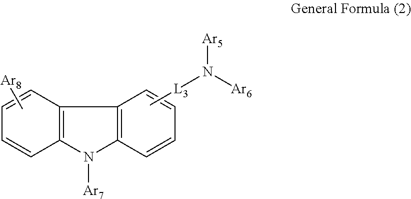

In the above General Formula (2), Ar₅, Ar₆, and Ar₇ are each independently a substituted or unsubstituted aryl group having 6 to 50 ring carbon atoms or a substituted or unsubstituted heteroaryl group having 5 to 50 ring carbon atoms, Ar₈ is a substituted or unsubstituted aryl group having 6 to 50 ring carbon atoms, a substituted or unsubstituted heteroaryl group having 5 to 50 ring carbon atoms or a substituted or unsubstituted alkyl group having 1 to 50 carbon atoms, L₃ is a direct linkage, a substituted or unsubstituted arylene group having 6 to 50 ring carbon atoms or a substituted or unsubstituted heteroarylene group having 5 to 50 ring carbon atoms.

Examples of Ar₅, Ar₆, and Ar₇ may include a phenyl group, a biphenyl group, a terphenyl group, a naphthyl group, an anthryl group, a phenanthryl group, a fluorenyl group, an indenyl group, a pyrenyl group, an acetonaphthenyl group, a fluoranthenyl group, a triphenylenyl group, a pyridyl group, a furanyl group, a pyranyl group, a thienyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a pyrazolyl group, a dibenzofuranyl group, a dibenzothienyl group, etc. For example Ar₅, Ar₆, and Ar₇ may be the phenyl group, the biphenyl group, the terphenyl group, the fluorenyl group, the carbazolyl group, the dibenzofuranyl group, etc.

Examples of Ar₈ may include a phenyl group, a biphenyl group, a terphenyl group, a naphthyl group, an anthryl group, a phenanthryl group, a fluorenyl group, an indenyl group, a pyrenyl group, an acetonaphthenyl group, a fluoranthenyl group, a triphenylenyl group, a pyridyl group, a furanyl group, a pyranyl group, a thienyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a pyrazolyl group, a dibenzofuranyl group, a dibenzothienyl group, etc. For example, Ar₈ may be the phenyl group, the biphenyl group, the terphenyl group, the fluorenyl group, the carbazolyl group, the dibenzofuranyl group, etc.

Examples of L₃ may include a phenylene group, a biphenylene group, a terphenylene group, a naphthalene group, an anthrylene group, a phenanthrylene group, a fluorenylene group, an indenylene group, a pyrenylene group, an acetonaphthenylene group, a fluoranthenylene group, a triphenylenylene group, a pyridylene group, a furanylene group, a pyranylene group, a thienylene group, a quinolylene group, an isoquinolylene group, a benzofuranylene group, a benzothienylene group, an indolylene group, a carbazolylene group, a benzoxazolylene group, a benzothiazolylene group, a kinokisariren group, a benzoimidazolylene group, a pyrazolylene group, a dibenzofuranylene group, a dibenzothienylene group, etc. For example, L₃ may be the direct linkage, the phenylene group, the biphenylene group, the terphenylene group, the fluorenylene group, the carbazolylene group or the dibenzofuranylene group.

Examples of the compound represented by General Formula (2) may include the following Compounds 2-1 to 2-16.

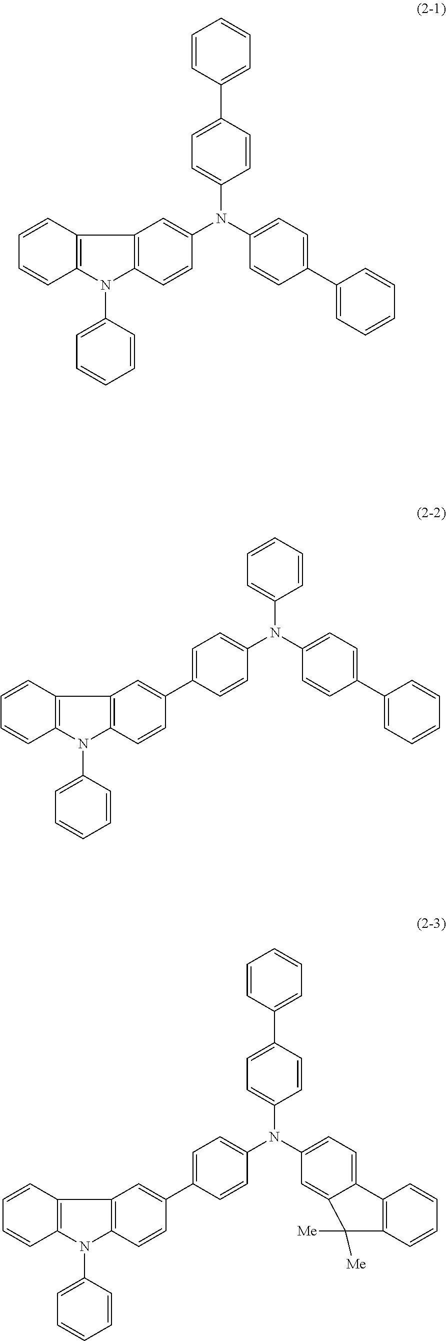

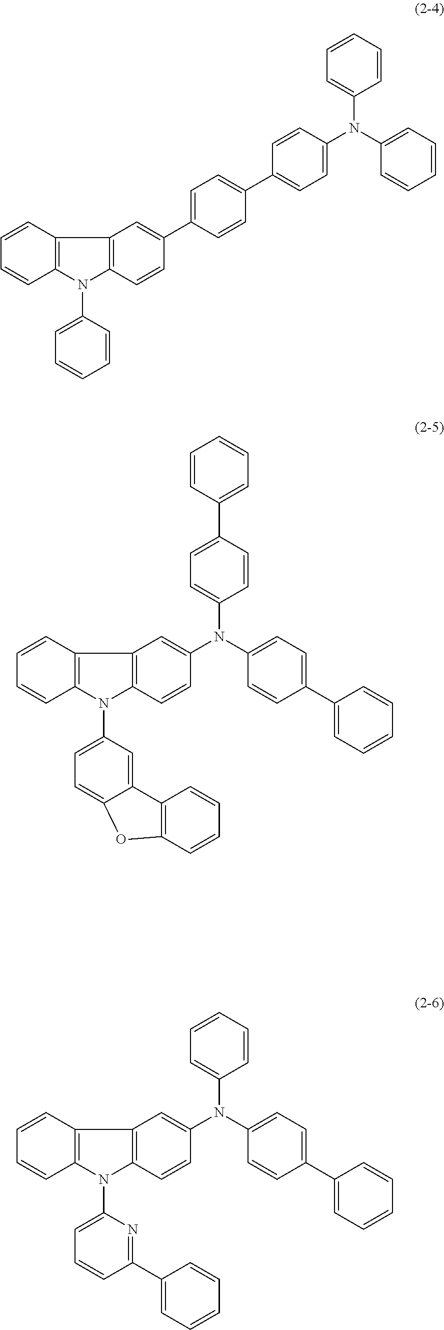

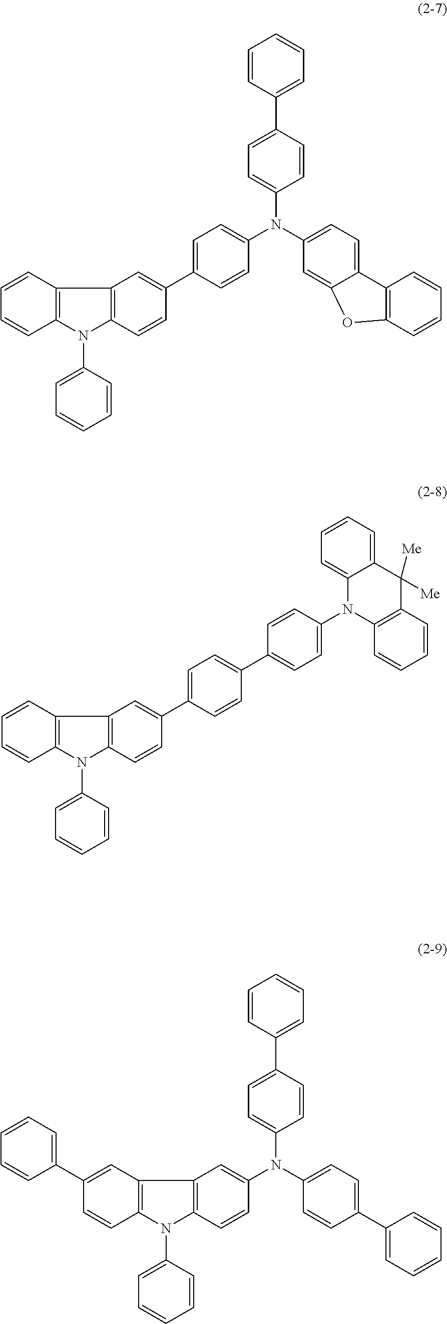

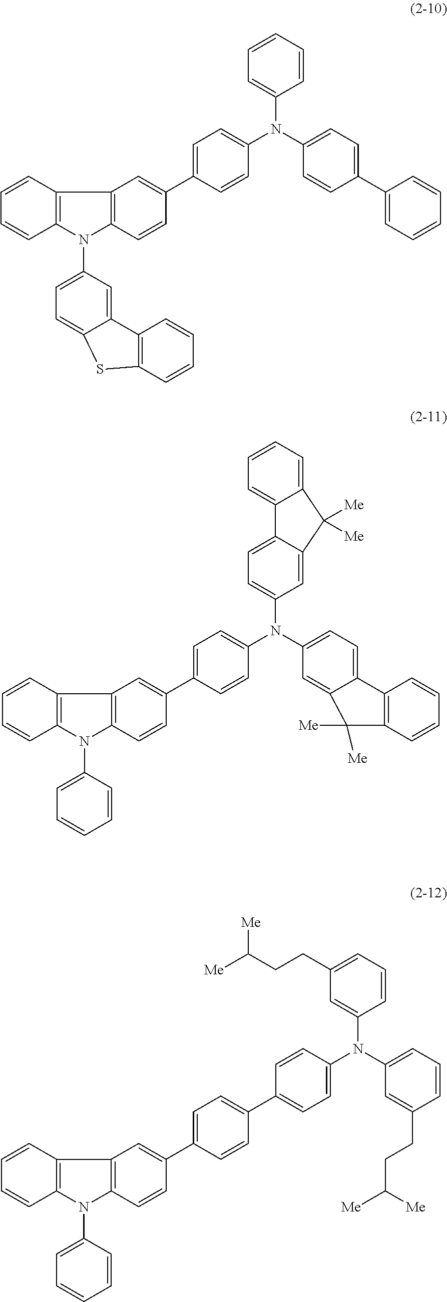

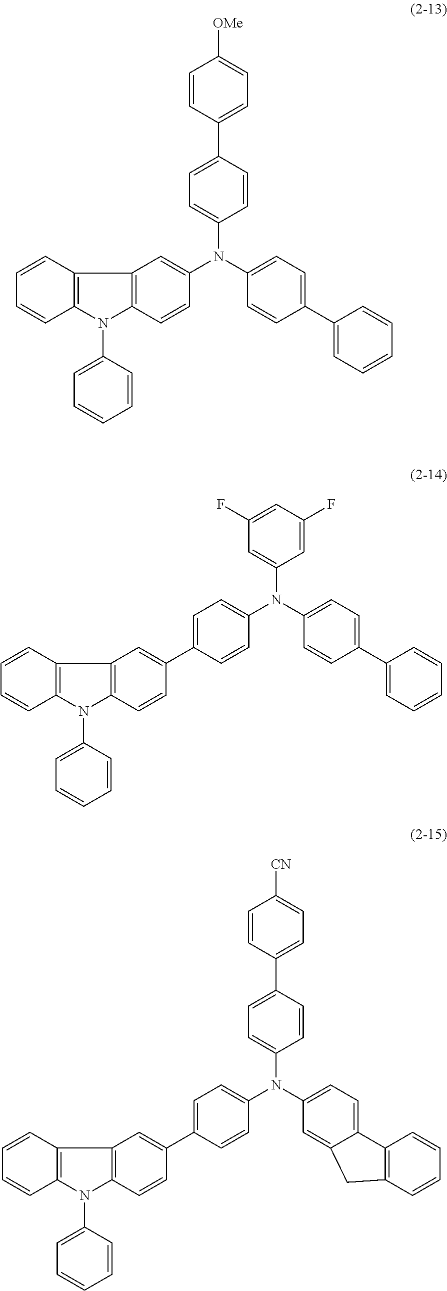

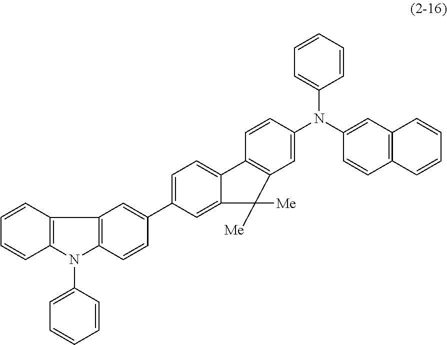

The intermediate hole transport material layer 133 may include the compound represented by the above General Formula (2). The intermediate hole transport material layer 133 may improve the hole transporting property of the hole transport layer 130 and may improve the emission property of the organic electroluminescent device 100.

(2-1-1-3. Configuration of Emission Layer-Side Hole Transport Layer)

The emission layer-side hole transport layer 135 may include a compound represented by the following General Formula (1). The emission layer-side hole transport layer 135 may be formed, for example, on the intermediate hole transport material layer 133, adjacent to the emission layer 140.

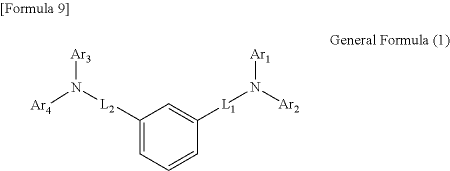

In the above General Formula (1), Ar₁, Ar₂, Ar₃, and Ar₄ may each independently be a substituted or unsubstituted aryl group having 6 to 50 ring carbon atoms or a substituted or unsubstituted heteroaryl group having 5 to 50 ring carbon atoms, and L₁ and L₂ are each independently a direct linkage, a substituted or unsubstituted arylene group having 6 to 18 ring carbon atoms or a substituted or unsubstituted heteroarylene group having 5 to 15 ring carbon atoms.

Examples of Ar₁, Ar₂, Ar₃, and Ar₄ may include a phenyl group, a biphenyl group, a terphenyl group, a naphthyl group, an anthryl group, a phenanthryl group, a fluorenyl group, an indenyl group, a pyrenyl group, an acetonaphthenyl group, a fluoranthenyl group, a triphenylenyl group, a pyridyl group, a furanyl group, a pyranyl group, a thienyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a pyrazolyl group, a dibenzofuranyl group, a dibenzothienyl group, etc. For example, Ar₁-Ar₄ may independently be the phenyl group, the biphenyl group, the terphenyl group, the fluorenyl group, the carbazolyl group, the dibenzofuranyl group, etc.

Examples of L₁ and L₂ other than the direct linkage may include a substituent illustrated in the above Ar₁, Ar₂, Ar₃, and Ar₄, except in the form of a divalent substituent. Examples of L₁ and L₂ other than the direct linkage, may include the phenylene group, the naphthalene group, the biphenynylene group, the thienothiophenylene group and the pyridylene group. For example, L₁ and L₂ may be the direct linkage, the phenylene group or the biphenynylene group.

Examples of the compound represented by General Formula (1) may include the following Compounds 1-1 to 1-26.

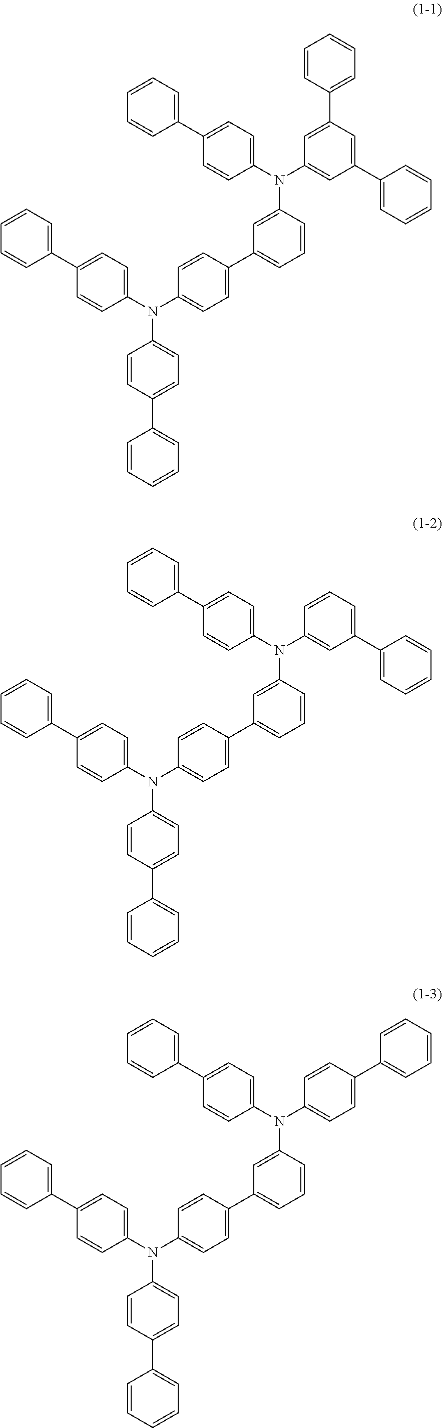

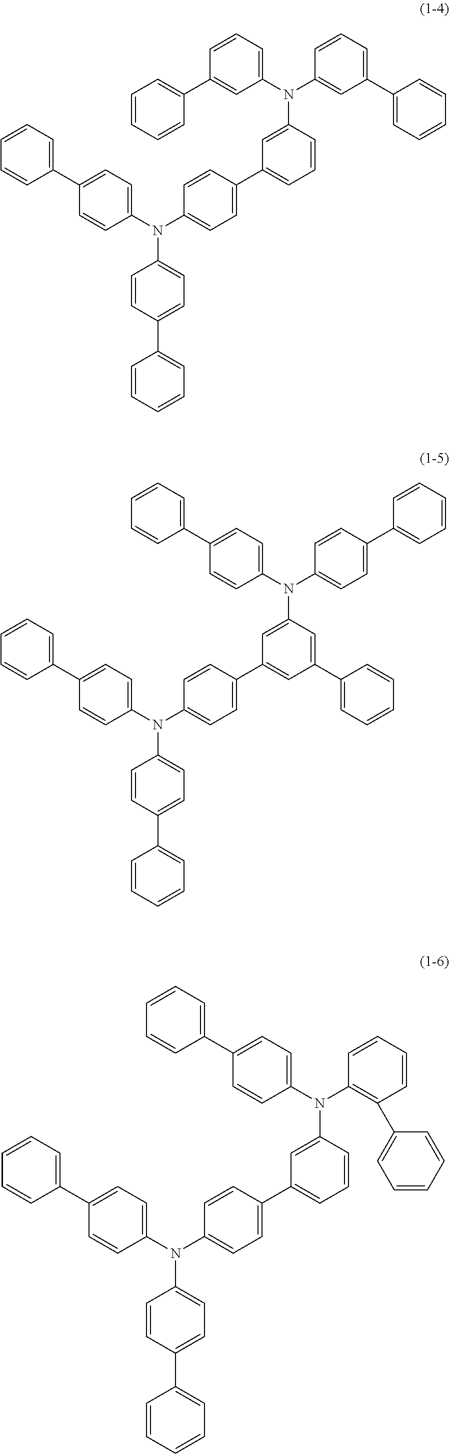

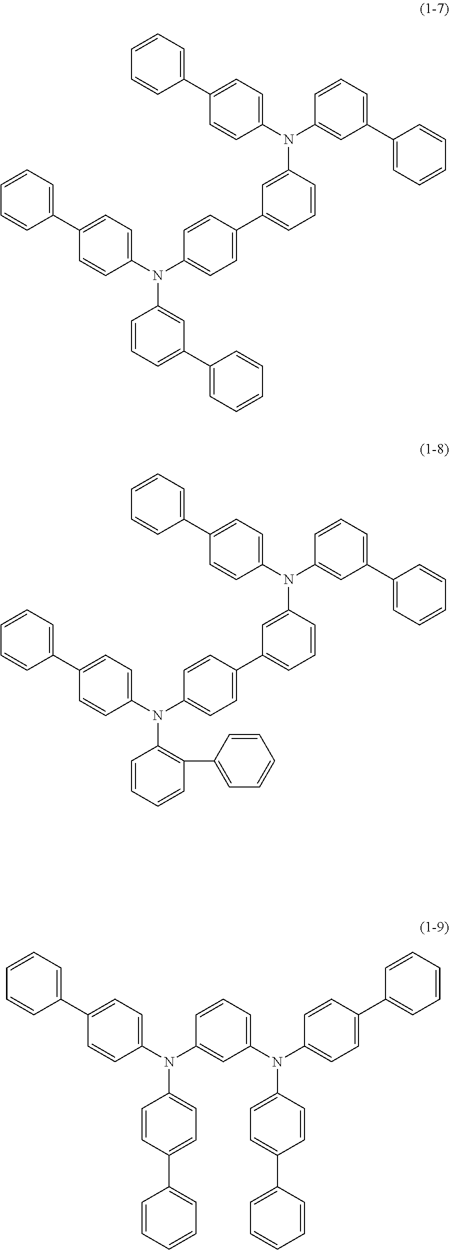

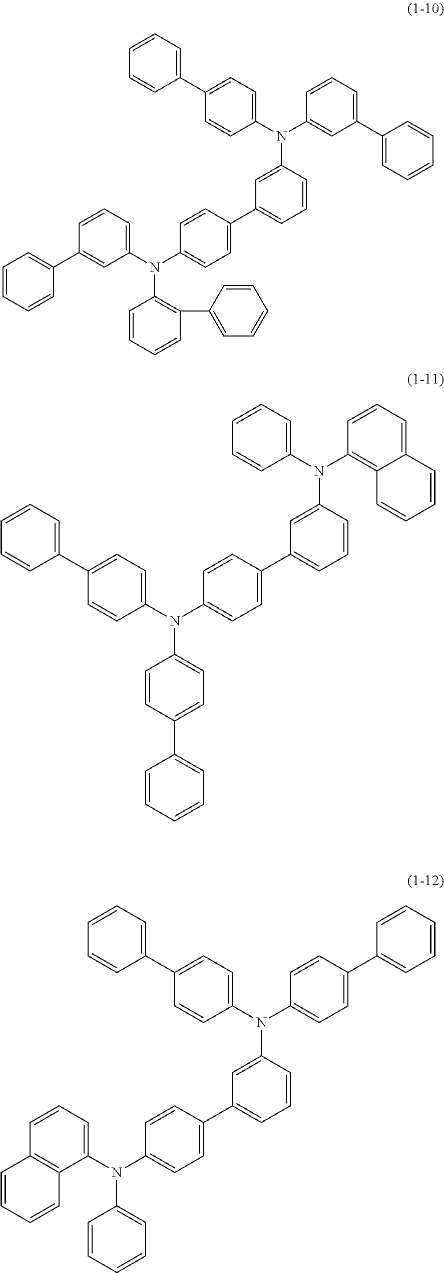

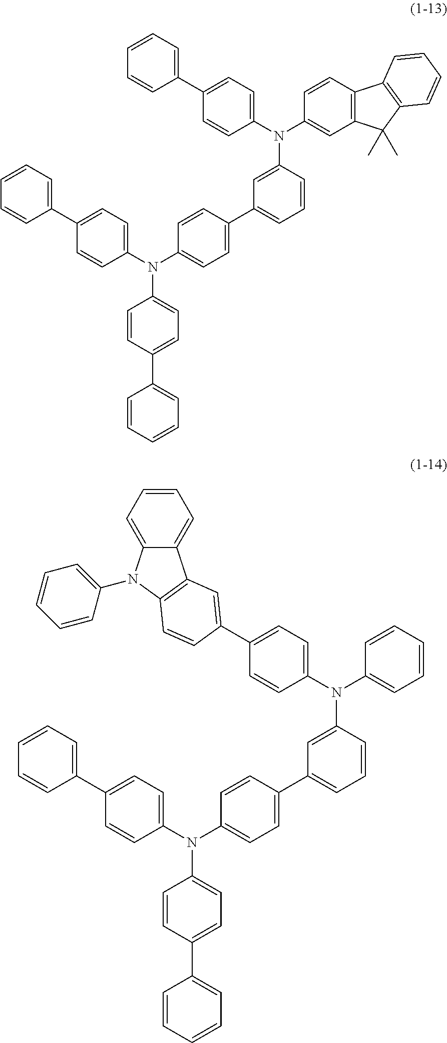

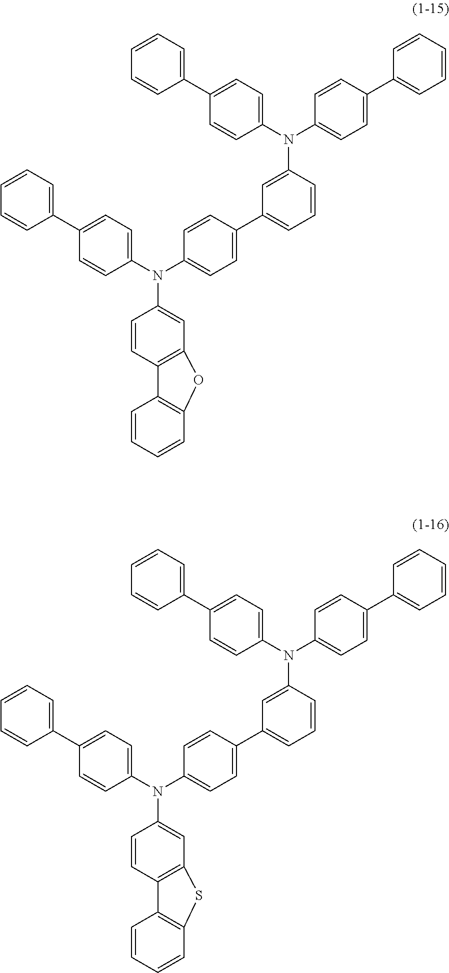

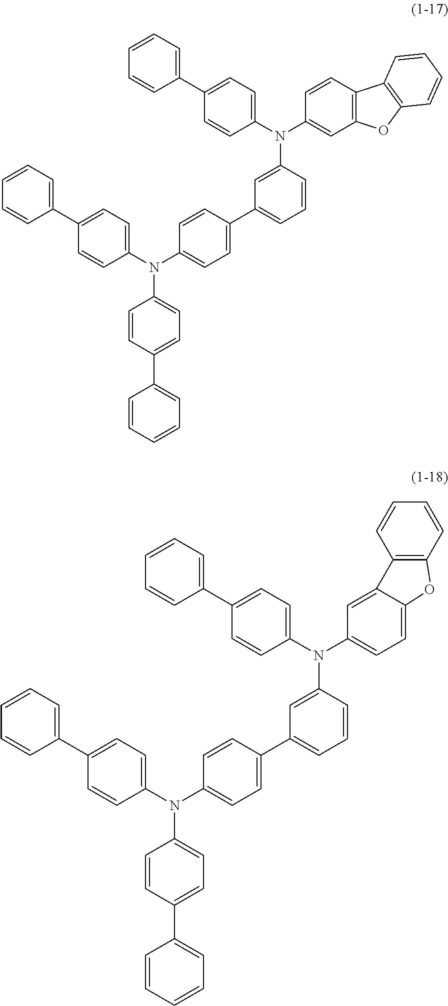

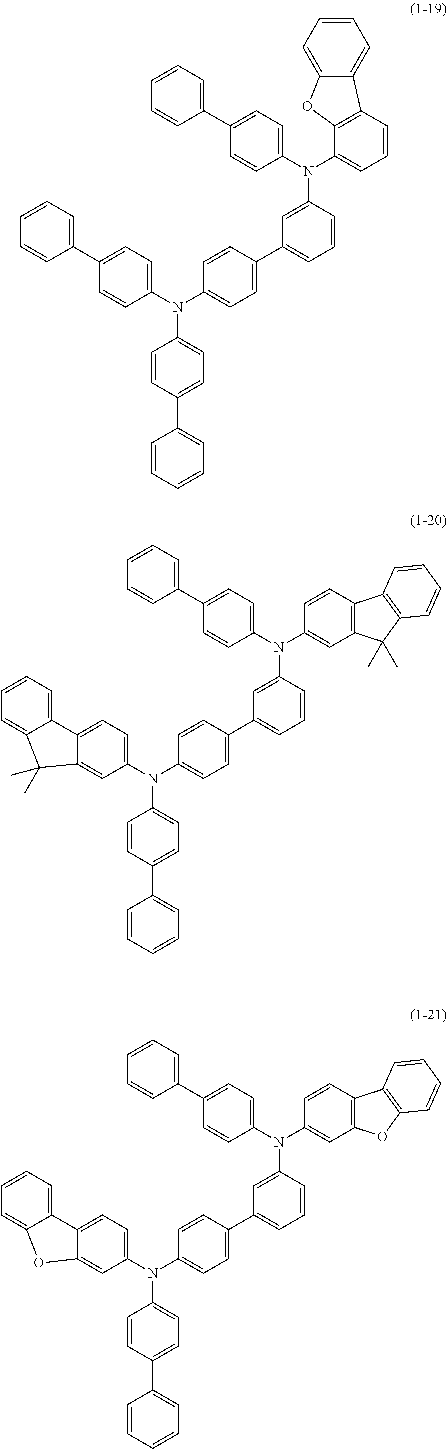

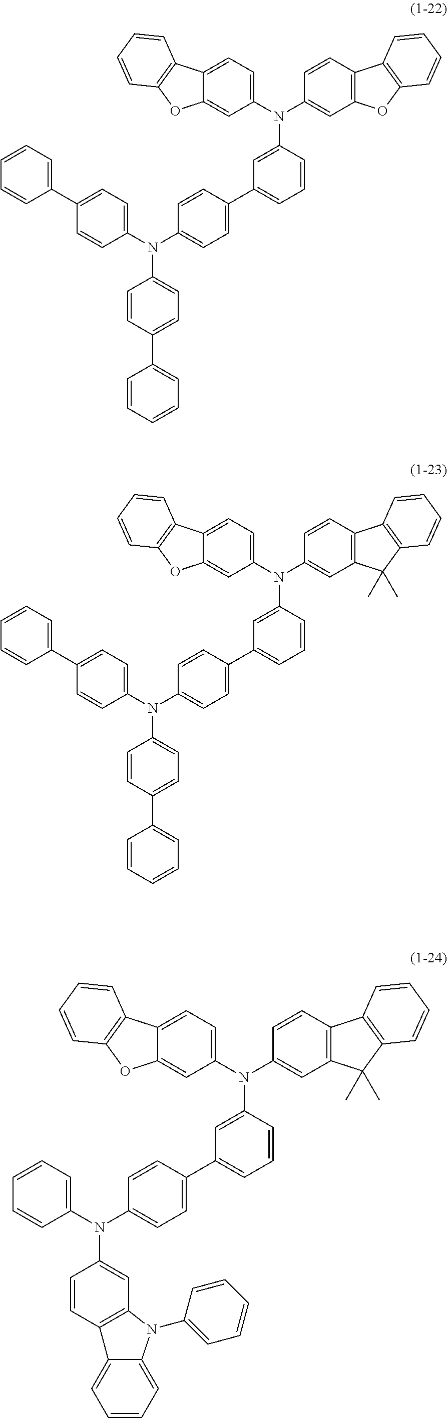

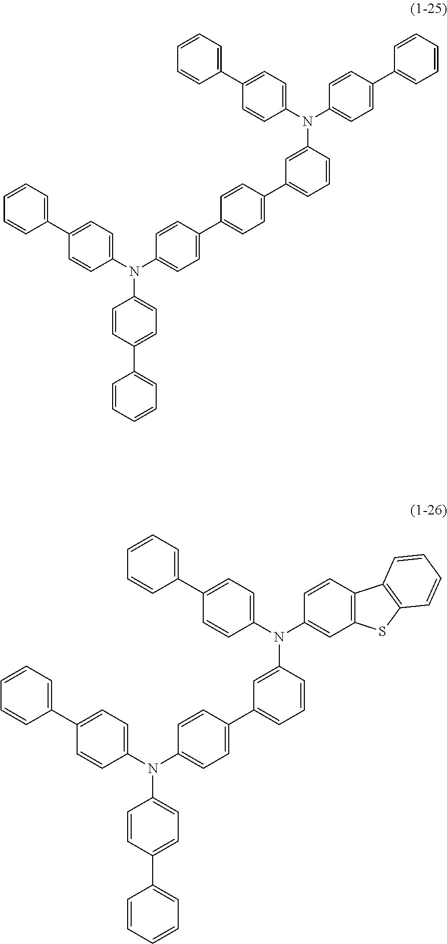

The emission layer-side hole transport layer 135 may include the compound represented by the above General Formula (1) as the emission layer-side hole transport material. The emission layer-side hole transport layer 135 may protect the hole transport layer 130 from electrons not consumed in the emission layer 140. When the emission layer-side hole transport layer 135 includes the compound represented by the above General Formula (1), the diffusion of the energy of an excited state generated in the emission layer 140 to the hole transport layer 130 may be reduced or prevented. Thus, according to this configuration, the emission layer-side hole transport layer 135 may improve the current flow durability of the hole transport layer 130.

The emission layer-side hole transport layer 135 may be formed near the emission layer 140, for example, adjacent to the emission layer 140 to effectively help prevent the diffusion of electrons or energy from the emission layer 140.

In addition, when the emission layer-side hole transport layer 135 includes the compound represented by the above General Formula (1), the charge balance of the whole organic electroluminescent device 100 may be controlled, and the diffusion of the electron accepting material included in the anode-side hole transport layer 131 into the emission layer 140 may be restrained. Accordingly, the emission layer-side hole transport layer 135 may improve the charge transport property of the hole transport layer 130.

When the emission layer-side hole transport layer 135 includes the compound represented by the above General Formula (1), the current flow durability of the hole transport layer 130 may be improved, thereby improving the emission life of the organic electroluminescent device 100.

As described above, the hole transport layer 130 including the anode-side hole transport layer 131, the intermediate hole transport material layer 133 and the emission layer-side hole transport layer 135 may improve the current flow durability and hole transport property of the organic electroluminescent device 100. Thus, the organic electroluminescent device 100 according to an embodiment may have improved emission life.

### 2-2. Examples

Hereinafter, the organic electroluminescent devices according to exemplary embodiments will be explained in particular referring to examples and comparative examples. In addition, the following embodiments are only for illustration, and the organic electroluminescent devices according to exemplary embodiments are not limited thereto.

### 2-2-1. Manufacture of Organic Electroluminescent Device Including Anode-Side Hole Transport Material Including Mainly Electron Accepting Material

An organic electroluminescent device according to an embodiment was manufactured by the following manufacturing method.

First, with respect to an ITO-glass substrate patterned and washed in advance, surface treatment using UV-Ozone (O₃) was conducted. The layer thickness of an ITO layer (first electrode) on a glass substrate was about 150 nm. After ozone treatment, the substrate was washed and inserted in a glass bell jar type evaporator for forming an organic layer. An anode-side hole transport layer, an intermediate hole transport material layer, an emission layer-side hole transport layer, an emission layer and an electron transport layer were evaporated one by one with a vacuum degree of about 10⁻⁴ to about 10⁻⁵ Pa. The layer thickness of each of the anode-side hole transport layer, the intermediate hole transport material layer and the emission layer-side hole transport layer was about 10 nm. The layer thickness of the emission layer was about 25 nm, and the layer thickness of the electron transport layer was about 25 nm. Then, the substrate was moved into a glass bell jar type evaporator for forming a metal layer, and the electron injection layer and the second electrode were evaporated with a vacuum degree of about 10⁻⁴ to about 10⁻⁵ Pa. The layer thickness of the electron injection layer was about 1 nm and the layer thickness of the second electrode was about 100 nm.

The anode-side hole transport layer, the intermediate hole transport material layer and the emission layer-side hole transport layer correspond to the hole transport layer with a stacked structure. The anode-side hole transport layer, the intermediate hole transport material layer and the emission layer-side hole transport layer were manufactured in examples and comparative examples using the materials shown in the following Table 2.

In addition, Compounds 6-1 and 6-2 mean common hole transport materials represented by the following formulae.

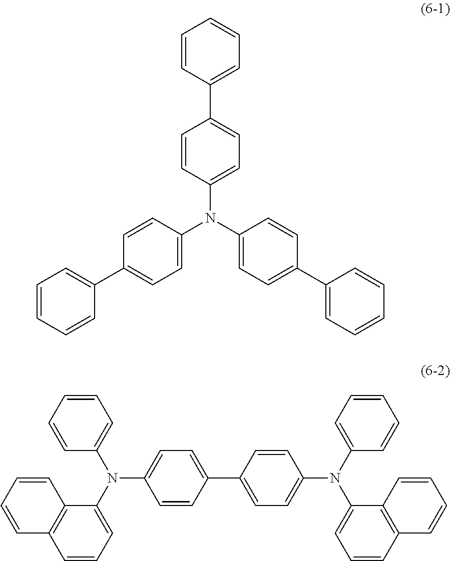 [SMILES: c1ccc(-c2ccc(N(c3ccc(-c4ccccc4)cc3)c3ccc(-c4ccccc4)cc3)cc2)cc1 ; c1ccc(N(c2ccc(-c3ccc(N(c4ccccc4)c4cccc5ccccc45)cc3)cc2)c2cccc3ccccc23)cc1]

As the host material of the emission layer, ADN (Compound 3-2) was used, and as the dopant material. TBP was used. In addition, the dopant material was added in an amount of about 3 wt % on the basis of the amount of the host material. The electron transport layer was formed using Alq3, the electron injection layer was formed using LiF, and the second electrode was formed using aluminum (Al).

### 2-2-2. Evaluation Results

The emission life of the organic electroluminescent device thus manufactured was evaluated. The evaluation results are shown together in the following Table 2. In addition, the half life of examples and comparative examples were obtained by measuring with current density of about 10 mA/cm² and initial luminance of about 1,000 cd/m². The half life in Table 2 is shown as a relative ratio with the half life of Comparative Example 2-1 as being 1. In addition, the measurement was conducted using a source meter of 2400 series of Keithley Instruments Co., Color brightness photometer CS-200 (Konica Minolta holdings, measurement angle of 1°), and a PC program LabVIEW8.2 (National instruments in Japan) for measurement in a dark room.

TABLE 2

| | | Intermediate | Emission layer- | | |
|---|---|---|---|---|---|
| | Anode-side hole | hole transport | side hole | Driving | Emission |
| | transport layer | material layer | transport layer | voltage [V] | life |
| Example 2-1 | Compound 4-15 | Compound 2-3 | Compound 1-3 | 6.5 | 1.40 |
| Example 2-2 | Compound 4-15 | Compound 6-2 | Compound 1-3 | 6.5 | 1.19 |
| Comparative | Compound 1-3 | Compound 4-15 | Compound 1-3 | 6.9 | 1.00 |
| Example 2-1 | | | | | |
| Comparative | Compound 4-15 | Compound 1-3 | Compound 2-3 | 6.9 | 0.83 |
| Example 2-2 | | | | | |
| Comparative | Compound 4-15 | Compound 2-3 | Compound 6-1 | 6.5 | 0.92 |
| Example 2-3 | | | | | |

Referring to the results in Table 2, it can be seen that the emission life was increased for the organic electroluminescent devices of Examples 2-1 and 2-2 when compared to those of Comparative Examples 2-1 to 2-3. Thus, it can be seen that the emission life of the organic electroluminescent device was increased by providing the anode-side hole transport layer, the intermediate hole transport material layer and the emission layer-side hole transport layer between the first electrode and the emission layer.

When comparing Example 2-1 with Comparative Example 2-3, it can be seen that the properties of Example 2-1 were good. In Comparative Example 2-3, in the emission layer-side hole transport material included in the emission layer-side hole transport layer, a common hole transport material, Compound 6-1 was used instead the compound represented by General Formula (1). It can be seen that the inclusion of the compound represented by General Formula (1) in the emission layer-side hole transport layer provided a superior emission life.

When comparing Example 2-1 with Comparative Example 2-2, it can be seen that the properties of Example 2-1 were good. In Comparative Example 2-2, the compounds included in the intermediate hole transport material and the emission layer-side hole transport layer were different from from the compound included in Example 2-1. It can be seen that the provision of the emission layer-side hole transport layer including the compound represented by General Formula (1) adjacent to the emission layer according to Example 2-1 provided a superior emission life.

When comparing Example 2-1 with Comparative Example 2-1, it can be seen that the properties of Example 2-1 were good. In Comparative Example 2-1, a layer formed using mainly the electron accepting material, Compound 4-15 was inserted between layers including Compound 1-3 represented by General Formula (1), and was provided at a position corresponding to the intermediate hole transport material layer. It can be seen, the provision of the anode-side hole transport layer including mainly the electron accepting material near the first electrode (anode) according to Example 2-1 provided a superior emission life.

When comparing Example 2-1 with Example 2-2, it can be seen that the properties of Example 2-1 were good. In Example 2-2, in the intermediate hole transport material included in the intermediate hole transport material layer, a common hole transport material, Compound 6-2 was used instead of Compound 2-3 represented by General Formula (2). It can be seen that the inclusion of the compound represented by General Formula (2) in the intermediate hole transport material layer according to Example 2-1 provided a superior emission life.

As described above, according to exemplary embodiments, when the anode-side hole transport layer including mainly the electron accepting material, the intermediate hole transport material layer and the emission layer-side hole transport layer including the compound represented by General Formula (1) were stacked between the first electrode (anode) and the emission layer, the emission life of the organic electroluminescent device may be increased.

By disposing the emission layer-side hole transport layer including the compound represented by General Formula (1), the emission layer-side hole transport layer may protect the hole transport layer from electrons not consumed in the emission layer and may help prevent the diffusion of excited state energy generated in the emission layer into the hole transport layer, thereby controlling the charge balance of the whole device. By disposing the emission layer-side hole transport layer including the compound represented by General Formula (1), the emission layer-side hole transport layer may restrain the diffusion of the electron accepting material included in the anode-side hole transport layer provided near the first electrode (anode) into the emission layer.

By way of summation and review, an organic electroluminescent device may include a hole transport material or a hole transport layer. A carbazolyl group may be used in a hole transport layer, and an electron accepting material may be added into a hole transport layer. A plurality of hole transport layers may be formed as a stacked structure. However, further improvement of an organic electroluminescent device is desirable to provide satisfactory values on the driving voltage and the emission life of an organic electroluminescent device.

Embodiments provide an organic electroluminescent device having a decreased driving voltage and improved emission life. According to embodiments, an anode-side hole transport layer, an intermediate hole transport material layer, and an emission layer-side hole transport layer are provided between an anode and an emission layer, and the driving voltage of an organic electroluminescent device may be decreased, and the emission life thereof may be increased

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof as set forth in the following claims.

What is claimed is:

1. An organic electroluminescent device, comprising:
an anode;
an emission layer;
an anode-side hole transport layer on the anode and the emission layer, the anode-side hole transport layer including an anode-side hole transport material and the anode-side hole transport layer being doped with an electron accepting material;
an intermediate hole transport material layer between the anode-side hole transport layer and the emission layer, the intermediate hole transport layer including an intermediate hole transport material; and
an emission layer-side hole transport material between the intermediate hole transport material layer and the emission layer and adjacent to the emission layer, the emission layer-side hole transport material layer including an emission layer-side hole transport material represented by the following General Formula (1): 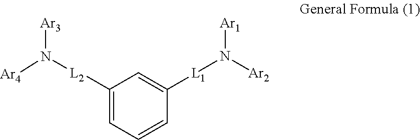
wherein, in the above General Formula (1),
Ar₁, Ar₂, Ar₃, and Ar₄ are each independently a substituted or unsubstituted aryl group having 6 to 50 ring carbon atoms or a substituted or unsubstituted heteroaryl group having 5 to 50 ring carbon atoms, and
L₁ and L₂ are each independently a direct linkage, a substituted or unsubstituted arylene group having 6 to 18 ring carbon atoms, or a substituted or unsubstituted heteroarylene group having 5 to 15 ring carbon atoms.

2. The organic electroluminescent device as claimed in claim 1, wherein the intermediate hole transport material is a compound represented by the following General Formula (2): 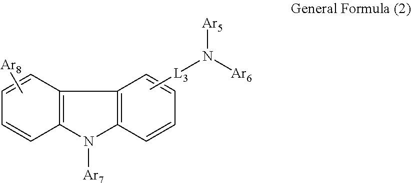
wherein, in the above General Formula (2),
Ar₅, Ar₆, and Ar₇ are each independently a substituted or unsubstituted aryl group having 6 to 50 ring carbon atoms or a substituted or unsubstituted heteroaryl group having 5 to 50 ring carbon atoms,
Ar₈ is a substituted or unsubstituted aryl group having 6 to 50 ring carbon atoms, a substituted or unsubstituted heteroaryl group having 5 to 50 ring carbon atoms, or a substituted or unsubstituted alkyl group having 1 to 50 carbon atoms, and
L₃ is a direct linkage, a substituted or unsubstituted arylene group having 6 to 50 ring carbon atoms, or a substituted or unsubstituted heteroarylene group having 5 to 50 ring carbon atoms.

3. The organic electroluminescent device as claimed in claim 1, wherein the electron accepting material has a lowest unoccupied molecular orbital (LUMO) level of from about −9.0 eV to about −4.0 eV.

4. The organic electroluminescent device as claimed in claim 1, wherein the anode-side hole transport layer is adjacent to the anode.

5. The organic electroluminescent device as claimed in claim 1, wherein the anode-side hole transport material of the anode-side hole transport layer is a compound represented by the following General Formula (2): 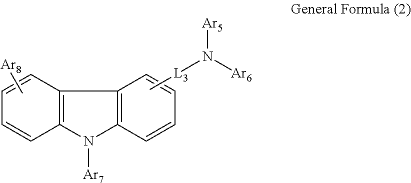
wherein, in the above General Formula (2),
Ar₅, Ar₆, and Ar₇ are each independently a substituted or unsubstituted aryl group having 6 to 50 ring carbon atoms or a substituted or unsubstituted heteroaryl group having 5 to 50 ring carbon atoms,
Ar₈ is a substituted or unsubstituted aryl group having 6 to 50 ring carbon atoms, a substituted or unsubstituted heteroaryl group having 5 to 50 ring carbon atoms, or a substituted or unsubstituted alkyl group having 1 to 50 carbon atoms, and
L₃ is a direct linkage, a substituted or unsubstituted arylene group having 6 to 50 ring carbon atoms, or a substituted or unsubstituted heteroarylene group having 5 to 50 ring carbon atoms.

6. The organic electroluminescent device as claimed in claim 1, wherein the emission layer includes an emission material that emits light via a singlet excited state.

7. The organic electroluminescent device as claimed in claim 1, wherein the emission layer includes a compound represented by the following General Formula (3): 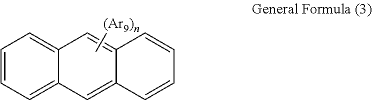
wherein, in the above General Formula (3),
each Ar₉ is independently a hydrogen atom, a deuterium atom, a substituted or unsubstituted alkyl group having 1 to 50 carbon atoms, a substituted or unsubstituted cycloalkyl group having 3 to 50 ring carbon atoms, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 ring carbon atoms, a substituted or unsubstituted arylthio group having 6 to 50 ring carbon atoms, a substituted or unsubstituted alkoxycarbonyl group having 2 to 50 carbon atoms, a substituted or unsubstituted aryl group having 6 to 50 ring carbon atoms, a substituted or unsubstituted heteroaryl group having 5 to 50 ring carbon atoms, a substituted or unsubstituted silyl group, a carboxyl group, a halogen atom, a cyano group, a nitro group or a hydroxyl group, and
n is an integer from 1 to 10.

8. An organic electroluminescent device, comprising:
an anode;
an emission layer;
an anode-side hole transport layer between the anode and the emission layer, the anode-side hole transport layer including an electron accepting material;
an intermediate hole transport material layer provided between the anode-side hole transport layer and the emission layer, the intermediate hole transport material layer including an intermediate hole transport material; and
an emission layer-side hole transport material layer between the intermediate hole transport material layer and the emission layer and adjacent to the emission layer, the emission layer-side hole transport material layer including an emission layer-side hole transport material represented by the following General Formula (1): 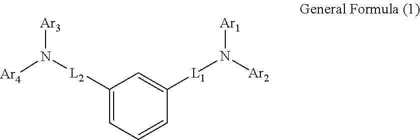
wherein, in the above General Formula (1),
Ar₁, Ar₃, and Ar₄ are each independently a substituted or unsubstituted aryl group having 6 to 50 ring carbon atoms or a substituted or unsubstituted heteroaryl group having 5 to 50 ring carbon atoms, and
L₁ and L₂ are each independently a direct linkage, a substituted or unsubstituted arylene group having 6 to 18 ring carbon atoms, or a substituted or unsubstituted heteroarylene group having 5 to 15 ring carbon atoms.

9. The organic electroluminescent device as claimed in claim 8, wherein the intermediate hole transport material is a compound represented by the following General Formula (2): 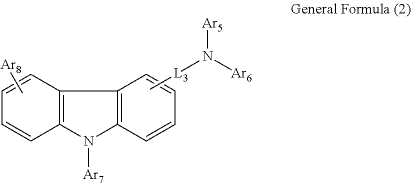
in the above General Formula (2),
Ar₅, Ar₆, and Ar₇ are each independently a substituted or unsubstituted aryl group having 6 to 50 ring carbon atoms or a substituted or unsubstituted heteroaryl group having 5 to 50 ring carbon atoms,
Ar₈ is a substituted or unsubstituted aryl group having 6 to 50 ring carbon atoms, a substituted or unsubstituted heteroaryl group having 5 to 50 ring carbon atoms, or a substituted or unsubstituted alkyl group having 1 to 50 carbon atoms, and
L₃ is a direct linkage, a substituted or unsubstituted arylene group having 6 to 50 ring carbon atoms, or a substituted or unsubstituted heteroarylene group having 5 to 50 ring carbon atoms.

10. The organic electroluminescent device as claimed in claim 8, wherein the electron accepting material has a lowest unoccupied molecular orbital (LUMO) level of from about −9.0 eV to about −4.0 eV.

11. The organic electroluminescent device as claimed in claim 8, wherein the anode-side hole transport layer is adjacent to the anode.

12. The organic electroluminescent device as claimed in claim 8, wherein the emission layer includes an emission material emitting light via a singlet excited state.

13. The organic electroluminescent device as claimed in claim 8, wherein the emission layer includes a compound represented by the following General Formula (3): 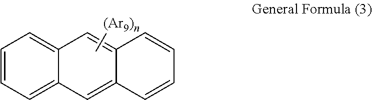
wherein, in the above General Formula (3),
each Ar₉ is independently a hydrogen atom, a deuterium atom, a substituted or unsubstituted alkyl group having 1 to 50 carbon atoms, a substituted or unsubstituted cycloalkyl group having 3 to 50 ring carbon atoms, a substituted or unsubstituted alkoxy group having 1 to 50 carbon atoms, a substituted or unsubstituted aralkyl group having 7 to 50 carbon atoms, a substituted or unsubstituted aryloxy group having 6 to 50 ring carbon atoms, a substituted or unsubstituted arylthio group having 6 to 50 ring carbon atoms, a substituted or unsubstituted alkoxycarbonyl group having 2 to 50 carbon atoms, a substituted or unsubstituted aryl group having 6 to 50 ring carbon atoms, a substituted or unsubstituted heteroaryl group having 5 to 50 ring carbon atoms, a substituted or unsubstituted silyl group, a carboxyl group, a halogen atom, a cyano group, a nitro group, or a hydroxyl group, and
n is an integer from 1 to 10.
